(19) United States
(12) Patent Application Publication
(10) Pub. No.: US 2026/0182123 A1
(43) Pub. Date: Jun. 25, 2026

(54) DISPLAY DEVICE AND ELECTRONIC DEVICES INCLUDING THE SAME

(71) Applicant: Samsung Display Co., Ltd., Yongin-si (KR)

(72) Inventors: Younjoo Lee, Yongin-si (KR); Kyungho Kim, Yongin-si (KR)

(21) Appl. No.: 19/425,445

(22) Filed: Dec. 18, 2025

(30) Foreign Application Priority Data
Dec. 20, 2024 (KR) 10-2024-0193312

(51) Int. Cl. H10H 29/85; H10H 29/34; H10H 29/49

(52) U.S. Cl. CPC H10H 29/8508; H10H 29/34; H10H 29/49

(57) ABSTRACT

A display device and an electronic device including the display device are provided. The display device may include a plurality of first areas separated from each other and including a light-emitting element, and a second area arranged between adjacent first areas selected from among the plurality of first areas, where a distance ratio of a first width of each of the plurality of first areas in a first direction to a first pitch by which the plurality of first areas are separated from each other may be about 0.2 to about 0.65.

### CROSS-REFERENCE TO RELATED APPLICATION

The present application claims priority to and the benefit of Korean Patent Application No. 10-2024-0193312, filed on Dec. 20, 2024, in the Korean Intellectual Property Office, the entire disclosure of which is incorporated herein by reference.

### BACKGROUND

### 1. Field

The present disclosure relates to a display device, for example, to a flexible display device and an electronic device include the display device.

### 2. Description of the Related Art

With the advancement of display technologies for visually presenting electrical signals, various display devices with desirable characteristics such as reduced thickness, lightweight construction, and/or low power consumption have been developed. For example, flexible display devices capable of being folded and/or rolled have been introduced. More recently, research and development efforts have focused on display devices with structures, such as stretchable displays capable of undergoing various shape transformations.

### SUMMARY

Aspects of the present disclosure are directed toward a display device, for example, a flexible display device and an electronic device include the display device. Additional aspects will be set forth in part in the description which follows and, in part, will be apparent from the description, or may be learned by practice of the presented embodiments of the disclosure.

According to one or more embodiments of the present disclosure, a display device may be provided. The display device may include a plurality of first areas separated from each other and including a light-emitting element, and a second area arranged between adjacent first areas selected from among the plurality of first areas, where a distance ratio of a first width of each of the plurality of first areas in a first direction to a first pitch by which the plurality of first areas are separated from each other may be about 0.2 to about 0.65.

In one or more embodiments, the display device may be stretchable in the first direction.

In one or more embodiments, in a second direction crossing the first direction, a ratio of a second width of each of the plurality of first areas to a second pitch by which the plurality of first areas in the second direction are separated from each other may be about 0.2 to about 0.65.

In one or more embodiments, the display device may be stretchable in the second direction.

In one or more embodiments, the plurality of first areas may include two adjacent first areas and the second area may connect the two adjacent first areas, and the first pitch may denote a shortest distance connecting center portions of the two adjacent first areas in a straight line along the first direction with the second area between the two adjacent first areas.

In one or more embodiments, the display device may further include a connecting line arranged in the second area and connecting the plurality of first areas.

In one or more embodiments, the connecting line may have a serpentine shape.

In one or more embodiments, the connecting line may include a stretchable and recoverable conductive material.

In one or more embodiments, an elongation of the stretchable and recoverable conductive material may be about 200% or less.

In one or more embodiments, the display device may further include a base layer including a stretchable and recoverable material, where the plurality of first areas may be arranged on the base layer.

In one or more embodiments, the plurality of first areas may have a first modulus and the second area may have a second modulus, and the first modulus may be greater than the second modulus.

In one or more embodiments, the plurality of first areas may have a multi-layer structure including a first layer, a second layer on the first layer, and a third layer on the second layer, and the first modulus may be a maximum modulus value among the first layer to the third layer.

In one or more embodiments, the plurality of first areas may have a multi-layer structure including a first layer, a second layer on the first layer, and a third layer on the second layer, and the first width may be based on a greatest width among widths of the first layer to the third layer, based on the first direction.

In one or more embodiments, a shape of each of the plurality of first areas may include a polygonal shape or a shape in which at least a portion may be rounded.

According to one or more embodiments of the present disclosure, a display device may be provided. The display device may include a plurality of island portions separated from each other and including a light-emitting element, and a plurality of bridge portions connecting adjacent island portions among the plurality of island portions, where a distance ratio of a first width of each of the plurality of island portions in an stretchable first direction to a first pitch by which the plurality of island portions are separated from each other may be about 0.2 to about 0.65.

In one or more embodiments, in a second direction crossing the first direction, a ratio of a second width of each of the plurality of island portions to a second pitch by which the plurality of island portions in the stretchable second direction are separated from each other may be about 0.2 to about 0.65.

In one or more embodiments, each of the plurality of bridge portions may have a serpentine shape.

In one or more embodiments, the plurality of island portions may include a first island portion and a second island portion, the first island portion being adjacent to the second island portion, and the plurality of island portions may include a first bridge portion connecting the first island portion to the second island portion, and the first pitch may denote a width connecting a center portion of the first island portion and a center portion of the second island portion in a straight distance along the first direction with the first bridge portion between the first island portion and the second island portion.

According to one or more embodiments of the present disclosure, an electronic device including the display device may be provided. The display device may include a plurality of first areas separated from each other and including a light-emitting element, and a second area arranged between adjacent first areas from among the plurality of first areas, where a distance ratio of a first width of each of the plurality of first areas in a first direction to a first pitch by which the plurality of first areas are separated from each other may be about 0.2 to about 0.65.

In one or more embodiments, the electronic device may further include a frame fixing the display device.

Aspects, features, and advantages other than those described above may become clear from the following drawings, the claims, and the detailed description of the disclosure.

These general and example aspects may be practiced utilizing a system, method, computer program, or any combination of systems, methods, and computer programs.

According to one or more embodiments of the present disclosure, a display device that may be stretched and recovered in one or more suitable directions and prevent or reduce damage caused by concentration of stress may be provided. For example, that display device is provided that is capable of being stretched and recovered in one or more directions without compromising structural integrity or display performance. By incorporating a plurality of discrete light-emitting areas (e.g., island portions) connected by stretchable bridge portions—such as serpentine-shaped conductive lines—the device may accommodate mechanical deformation while reducing or minimizing stress concentration. This structural configuration helps prevent or reduce damage typically caused by repeated stretching, bending, or twisting, thereby enhancing the mechanical durability and operational reliability of the display. These advantageous effects contribute to the development of flexible and stretchable electronic devices, including wearable displays, foldable smartphones, and/or conformable medical devices. Such effects are only examples and the scope of the present disclosure is not limited by the above effects.

### BRIEF DESCRIPTION OF DRAWINGS

FIG. 1 is a perspective view schematically showing a display device according to one or more embodiments of the present disclosure.

FIGS. 2A and 2B are perspective views showing the display device of FIG. 1 being stretched in a first direction.

FIG. 2C is a perspective view showing the display device of FIG. 1 being stretched in a second direction.

FIG. 2D is a perspective view showing the display device of FIG. 1 being stretched in the first direction and the second direction.

FIG. 2E is a perspective view showing the display device of FIG. 1 being stretched in a third direction.

FIG. 3 is a plan view schematically showing a display device according to one or more embodiments of the present disclosure.

FIG. 4 is a plan view schematically showing a portion (e.g., an excerpt) of a display area according to one or more embodiments of the present disclosure.

FIG. 5 is a cross-sectional view showing an excerpt of a first area and a second area.

FIGS. 6A-6C are each an equivalent circuit diagram of a pixel of a display device, according to one or more embodiments of the present disclosure.

FIGS. 7A-7E are each a cross-sectional view schematically showing a light-emitting diode of a display device, according to one or more embodiments of the present disclosure.

FIG. 8 is a plan view schematically showing a portion of a display area of a display device, according to one or more embodiments of the present disclosure.

FIG. 9 is a plan view schematically showing a portion of a display area of a display device, according to one or more embodiments of the present disclosure.

FIG. 10 is a plan view showing an excerpt of a portion of a display device, according to one or more embodiments of the present disclosure.

FIG. 11 is a cross-sectional view taken along a line A-A′ of FIG. 10.

FIGS. 12-14 are cross-sectional views showing excerpts of a portion of a display device, according to one or more embodiments of the present disclosure.

FIGS. 15A-15C are plan views schematically showing a portion of a display area of a display device, according to one or more embodiments of the present disclosure.

FIG. 16 is a plan view schematically showing a portion of a display area, according to one or more embodiments of the present disclosure.

FIGS. 17A and 17B are plan views schematically showing excerpts of a display area according to one or more embodiments of the present disclosure.

FIG. 18 is a cross-sectional view schematically showing a first island portion and a first bridge portion, which are arranged in a display area of a display device, according to one or more embodiments of the present disclosure.

FIG. 19A is a perspective view schematically showing an electronic device including a display device, according to one or more embodiments of the present disclosure.

FIG. 19B is a block diagram schematically showing an electronic device including a display device, according to one or more embodiments of the present disclosure.

FIGS. 20A-20G are each a perspective view schematically showing an example of an electronic device including a display device, according to one or more embodiments of the present disclosure.

### DETAILED DESCRIPTION

The present disclosure may have one or more suitable modifications and one or more suitable embodiments, and example embodiments are illustrated in the drawings and are described in more detail in the detailed description. Effects and features of the present disclosure and methods of achieving the same will become apparent with reference to one or more embodiments described in more detail with reference to the drawings. However, the present disclosure is not limited to the embodiments described in more detail, and may be implemented in one or more suitable forms.

Hereinafter, embodiments of the present disclosure will be described in more detail with reference to the accompanying drawings, and in the following description with reference to the drawings, like reference numerals refer to like components and redundant descriptions thereof will not be provided.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

One or more suitable embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved shapes and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure and equivalents thereof.

In the detailed description, for the purposes of explanation, numerous specific details are set forth to provide a thorough understanding of one or more suitable embodiments. It is apparent, however, that one or more suitable embodiments may be practiced without these specific details or with one or more equivalent arrangements. In other instances, well-known structures and devices are shown in block diagram form to avoid unnecessarily obscuring one or more suitable embodiments.

Spatially relative terms, such as “beneath,” “below,” “lower,” “under,” “above,” “upper,” and the like, may be utilized herein for ease of explanation to describe one element's relationship to another element(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements would then be oriented “above” the other elements. Thus, the example terms “below” and “under” can encompass both an orientation of above and below. The device may be otherwise oriented (e.g., rotated 90 degrees or at other orientations) and the spatially relative descriptors utilized herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in plan view,” means viewing a target portion from the top, and the phrase “on a cross-section” means viewing a cross-section formed by vertically cutting a target portion from the side.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As utilized herein, the term “and/or” includes any and all combinations of one or more of the associated listed items. For example, the expression such as “A and/or B” may include A, B, or A and B.

Further, the use of “may” when describing embodiments of the present disclosure refers to “one or more embodiments of the present disclosure”.

The same reference numerals refer to the same components. Further, in the drawings, the thickness, the ratio, and the dimension of components are exaggerated for effective description of technical contents. The expression “and/or” includes one or more combinations which associated components are capable of defining.

In the specification, the terms “first”, “second”, and/or the like may be utilized herein to describe one or more suitable components, the components should not limited by the terms. The terms are only utilized to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

In the specification, an expression utilized in the singular encompasses the expression of the plural, unless it has a clearly different meaning in the context.

In the specification, the terms “include/includes/including,” “comprise/comprises/comprising,” or “have/has/having” specify the presence of stated features, integers, numbers, steps, operations, elements, and/or components, but do not preclude the addition of one or more other features integers, numbers, steps, operations, elements, components, and/or groups thereof. Additionally, the terms “include/includes/including,” “comprise/comprises/comprising,” or “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the specification, the term “substantially,” “about,” “approximately,” and similar terms are utilized as terms of approximation and not as terms of degree, and are intended to account for the inherent deviations in measured or calculated values that would be recognized by those of ordinary skill in the art. “About” or “approximately,” as utilized herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. When one or more embodiments may be implemented differently, a specific process order may be performed differently from the described order. For example, two consecutively described processes may be performed substantially at the same time or performed in an order opposite to the described order.

In the specification, the term “substantially,” “about,” “approximately,” and similar terms are utilized as terms of approximation and not as terms of degree, and are intended to account for the inherent deviations in measured or calculated values that would be recognized by those of ordinary skill in the art. “About” or “approximately,” as utilized herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. When one or more embodiments may be implemented differently, a specific process order may be performed differently from the described order. For example, two consecutively described processes may be performed substantially at the same time or performed in an order opposite to the described order.

In the specification, if (e.g., when) a component (e.g., an element, an area, a layer, a part, a portion, a region, and/or the like) is referred to as being “on,” “formed on,” “disposed on,” “connected to,” “connected with,” or “coupled to” another component, this may refer that the component may be directly on, formed on, disposed on, connected to, connected with, or coupled to the other component and/or may be indirectly on, formed on, disposed on, connected to, connected with, or coupled to the other component with an intervening component therebetween. For example, in the specification, if (e.g., when) a component is electrically connected to another component, the component may be directly electrically connected thereto and/or may be indirectly electrically connected thereto with an intervening component therebetween. However, “directly connected/directly coupled” refers to one component directly connecting or coupling another component without any intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

In the specification, an x-axis, a y-axis, and a z-axis are not limited to three axes on an orthogonal coordinate system/a rectangular coordinate system, and may be interpreted in a broad sense including the three axes. For example, the x-axis, the y-axis, and the z-axis may be perpendicular to one another, or may represent different directions that are not perpendicular to one another. The same applies for first, second, and/or third directions.

In the specification, if (e.g., when) a certain embodiment is implemented differently, an example process order may be performed differently from the described order. For example, two consecutively described processes may be performed substantially at the same time or performed in an order opposite to the described order.

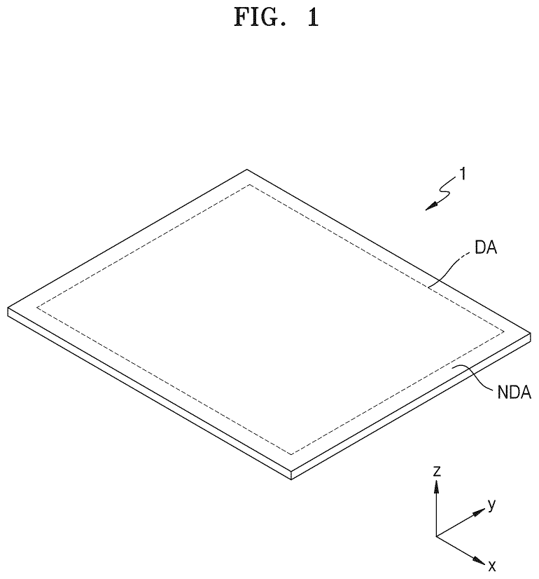

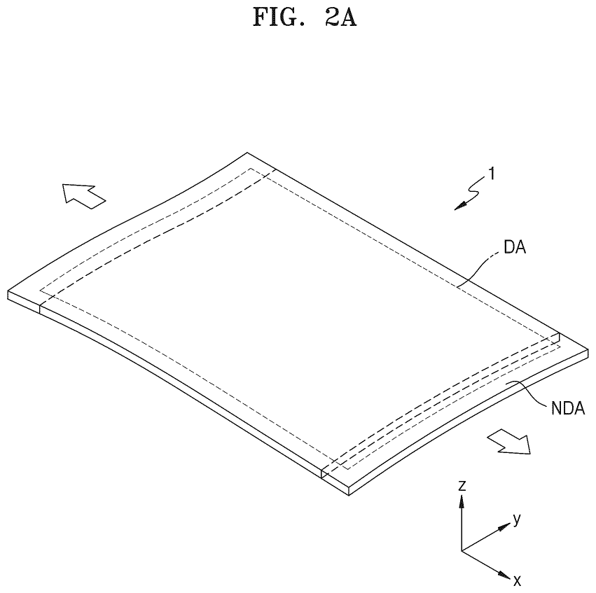

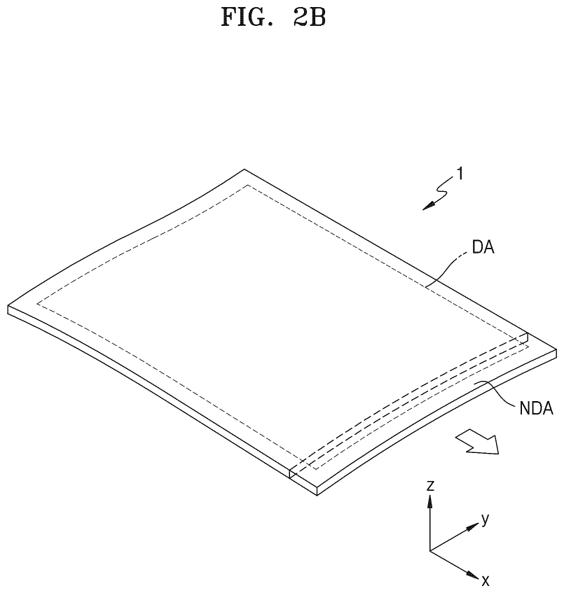

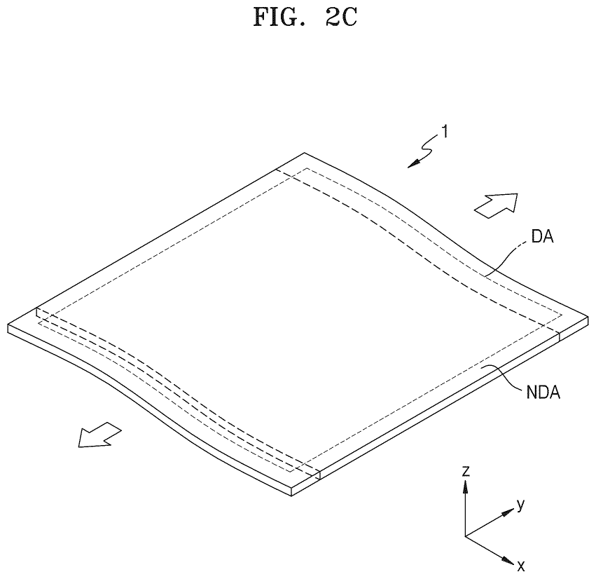

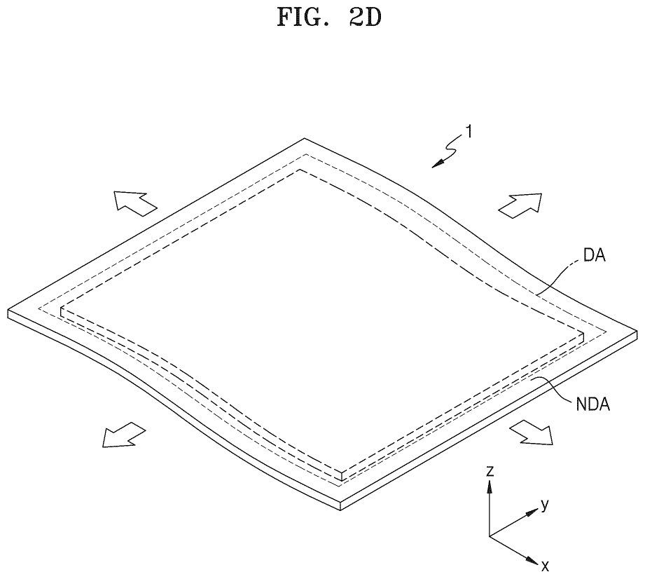

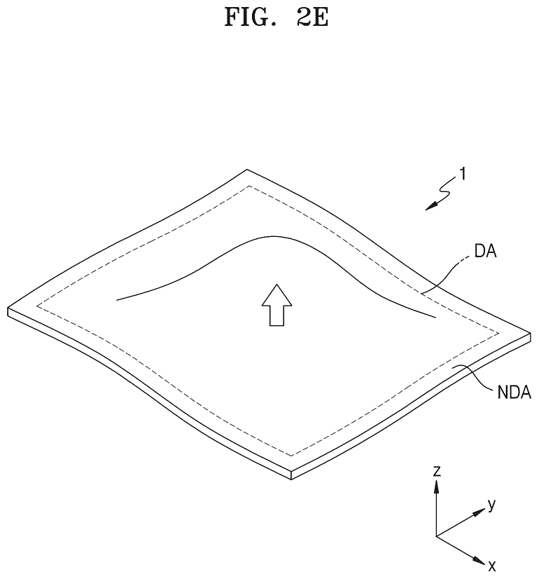

FIG. 1 is a perspective view schematically showing a display device 1 according to one or more embodiments of the present disclosure. FIGS. 2A and 2B are perspective views showing the display device 1 of FIG. 1 being stretched in a first direction. FIG. 2C is a perspective view showing the display device 1 of FIG. 1 being stretched in a second direction. FIG. 2D is a perspective view showing the display device of FIG. 1 being stretched in the first direction and the second direction. FIG. 2E is a perspective view showing the display device 1 of FIG. 1 being stretched in a third direction.

Referring to FIG. 1, the display device 1 may include a display area DA and a non-display area NDA. The display area DA may include a plurality of pixels. The display device 1 may provide an image by utilizing light emitted from the plurality of pixels. The non-display area NDA may be arranged outside the display area DA. The non-display area NDA may be an area where pixels are not arranged, and may entirely surround the display area DA.

The display device 1 may be configured to stretch and contract in one or more suitable directions. The display device 1 may be stretched in the first direction (e.g., an x direction and/or a −x direction) by external force applied by an external source/object or a user. According to one or more embodiments, as shown in FIGS. 2A and 2B, the display area DA and/or the non-display area NDA of the display device 1 may be stretched in the first direction (e.g., the x direction and/or the −x direction). For example, the display device 1 may be stretched along the x direction and the −x direction as shown in FIG. 2A, or along the x direction while one side of the display device 1 may be fixed as shown in FIG. 2B.

The display device 1 may be stretched in the second direction (e.g., a y direction and/or a −y direction) by external force applied by an external source/object or the user. According to one or more embodiments, as shown in FIG. 2C, the display area DA and/or the non-display area NDA of the display device 1 may be stretched in the y direction and the −y direction. According to one or more other embodiments, the display device 1 may be stretched in the y direction or the −y direction while one side of the display device 1 may be fixed.

The display device 1 may be stretched in a plurality of directions, e.g., the first direction (e.g., the x direction and/or the −x direction) and the second direction (e.g., the y direction and/or the −y direction), by external force applied by an external source/object or a part of the body of a person. As shown in FIG. 2D, the display area DA and/or the non-display area NDA of the display device 1 may be stretched in the ±x direction and the ty direction.

The display device 1 may be stretched in the third direction (e.g., a z direction or a −z direction) by external force applied by an external source/object or a part of the body of a person. According to one or more embodiments, FIG. 2E illustrates a portion of the display device 1, for example, a partial area of the display area DA, protruding in the z direction. According to one or more other embodiments, a portion of the display device 1, for example, a partial area of the display area DA, may protrude along the −z direction (or be dented along the z direction).

In FIGS. 2A to 2E, the display device 1 may be stretched in the first direction, the second direction, and/or the third direction, but the present disclosure is not limited thereto. According to one or more other embodiments, the display device 1 may be suitably transformed in an atypical shape, for example, may be bent and/or twisted with two or more axes.

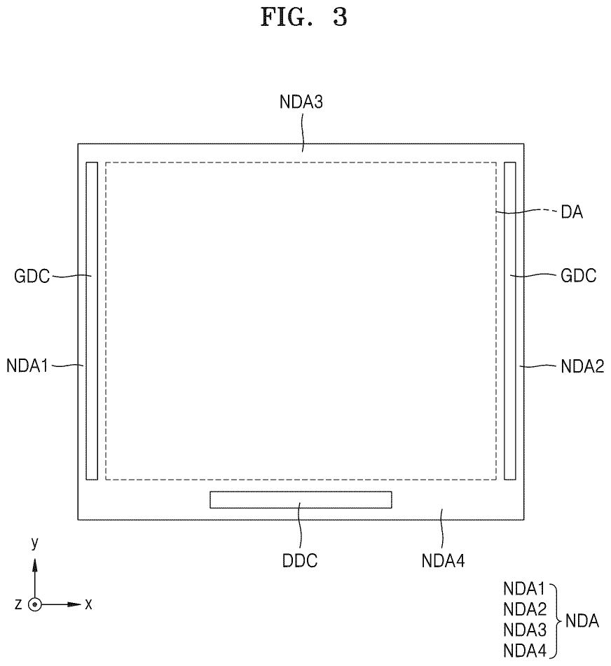

FIG. 3 is a plan view schematically showing the display device 1 according to one or more embodiments of the present disclosure.

The plurality of pixels may be arranged in (e.g., located at) the display area DA of the display device 1. Each pixel may include sub-pixels emitting light of different colors. A light-emitting element corresponding to each sub-pixel may be arranged in (e.g., located at) the display area DA. A circuit configured to provide electrical signals to the light-emitting elements arranged in (e.g., located at) the display area DA and transistors electrically connected to the light-emitting elements may be located in the non-display area NDA around (e.g., surrounding) the display area DA. A gate driving circuit GDC may be arranged in (e.g., located at) each of a first non-display area NDA1 and a second non-display area NDA2, which may be arranged on opposite sides with the display area DA therebetween. The gate driving circuit GDC may include drivers configured to provide electrical signals respectively to gate electrodes of the transistors electrically connected to the light-emitting elements. In FIG. 3, the gate driving circuit GDC may be arranged in (e.g., located at) each of the first non-display area NDA1 and the second non-display area NDA2, but the present disclosure is not limited thereto. According to one or more other embodiments, the gate driving circuit GDC may be arranged in (e.g., located at) one selected from among the first non-display area NDA1 and the second non-display area NDA2.

A data driving circuit DDC may be arranged in (e.g., located at) a third non-display area NDA3 and/or a fourth non-display area NDA4, which connect the first non-display area NDA1 and the second non-display area NDA2 to each other. For example, the third non-display area NDA3 and/or a fourth non-display area NDA4 may connect the first non-display area NDA1 to the second non-display area NDA2. According to one or more embodiments, FIG. 3 illustrates the data driving circuit DDC being arranged in (e.g., located at) the fourth non-display area NDA4. According to one or more other embodiments, the data driving circuit DDC may be arranged in (e.g., located at) each of the third non-display area NDA3 and the fourth non-display area NDA4.

FIG. 3 illustrates the data driving circuit DDC being arranged in (e.g., located at) the fourth non-display area NDA4 of the display device 1, but the present disclosure is not limited thereto. According to one or more other embodiments, the display device 1 may further include a flexible circuit board electrically connected through a terminal portion arranged in (e.g., located at) the fourth non-display area NDA4, and the data driving circuit DDC may be arranged on the flexible circuit board.

According to one or more embodiments, an elongation of the non-display area NDA may be equal to or lower than an elongation of the display area DA.

According to one or more embodiments, the elongation of the non-display area NDA may be different according to areas. For example, the first non-display area NDA1, the second non-display area NDA2, and the third non-display area NDA3 may have substantially the same elongation, but an elongation of the fourth non-display area NDA4 may be lower than the elongation of each of the first non-display area NDA1, the second non-display area NDA2, and the third non-display area NDA3. In the specification, an elongation (or strain) may be a value (ΔL/L×100 [%]) that represents a change (ΔL/L) in a length of a display device as a percentage if (e.g., when) external force may be applied to the display device in an elastic region of a stress-strain curve.

Here, ΔL denotes the amount of change in the length of the display device and L denotes the initial length of the display device.

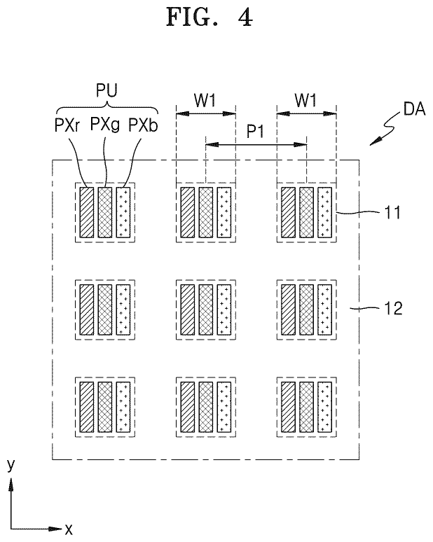

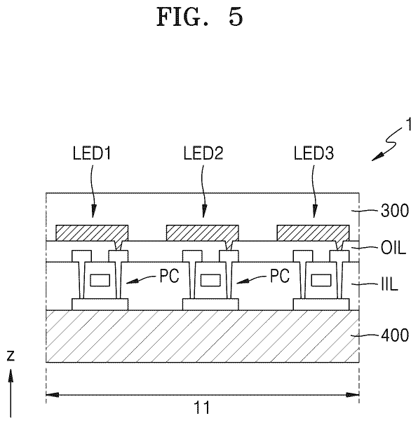

FIG. 4 is a plan view schematically showing a portion (e.g., an excerpt) of the display area DA of the display device 1, according to one or more embodiments of the present disclosure, and FIG. 5 is a cross-sectional view showing an excerpt of a first area and a second area.

Referring to FIG. 4, the display area DA may include first areas 11 and a second area 12 around (e.g., surrounding) each of the first areas 11. The first areas 11 may be repeatedly arranged in the first direction (e.g., the x direction) and in the second direction (e.g., the y direction).

The display area DA may include the first area 11 and the second area 12, which have different elongations. For example, the display device 1 (or a display panel) may include the first area 11 having a relatively small elongation and the second area 12 having a relatively large elongation. In the specification, the elongation may be a value that represents a change (ΔL/L) in a length by which the display device 1 may be stretchable without physical damage to the display device 1 if (e.g., when) external force may be applied to the display device 1. Here, ΔL denotes the amount of change in the length of the display device 1 and L denotes the initial length of the display device 1. Accordingly, the elongations of the first area 11 and the second area 12 may indicate changes in lengths of the first area 11 and the second area 12, respectively, if (e.g., when) substantially the same external force may be applied to the first area 11 and the second area 12.

The elongation of the first area 11 being smaller than the elongation of the second area 12 may indicate that deformation of the first area 11 occurs relatively less by external force. Accordingly, the first area 11 may be referred to as a low deformation area and the second area 12 may be referred to as a high deformation area. According to one or more embodiments, the first area 11 being a low deformation area may include a case where the elongation of the first area 11 may be substantially close to 0. Here, the first area 11 may be an area where deformation does not actually/substantially occur, and the second area 12 may be an area where deformation actually/substantially occurs. Because the first area 11 may be a low deformation area and the second area 12 may be a high deformation area, a modulus of the first area 11 may be greater than a modulus of the second area 12.

The first areas 11 may be spaced and/or apart (e.g., spaced apart or separated) from each other and arranged two-dimensionally in the display area DA. The first area 11 may be an area where the pixels are arranged, and accordingly, the first area 11 may be referred to as a pixel area or an emission area. One or more pixels may be arranged in (e.g., located at) each first area 11. For example, the first area 11 may include a pixel unit PU including a group of pixels, and each pixel unit PU may include a red pixel PXr, a green pixel PXg, and/or a blue pixel PXb.

The red pixel PXr, the green pixel PXg, and the blue pixel PXb may respectively include a first light-emitting diode LED1, a second light-emitting diode LED2, and/or a third light-emitting diode LED3.

Referring to FIG. 5, the first area 11 of the display device 1 may include a pixel circuit PC, an inorganic insulating stack IIL, an organic insulating layer OIL, the first, second, and third light-emitting diodes LED1, LED2, and LED3 electrically connected to the pixel circuits PC, and a protecting layer 300, which may be arranged on a base layer 400. The elongation of the first area 11 may be relatively smaller than the elongation of the second area 12 due to a stack structure of the pixel circuits PC, the inorganic insulating stack IIL, the organic insulating layer OIL, and the first, second, and third light-emitting diodes LED1, LED2, and LED3, which may be arranged in (e.g., located at) the first area 11.

The second area 12 may be located between adjacent first areas 11. As shown in FIG. 3, in plan view, the second area 12 may have a shape around (e.g., surrounding) each of the first areas 11. The second area 12 may be an area where a connecting line passes through, where the connecting line may be for connecting lines electrically connected to the pixel circuits PC (see FIG. 4) arranged in (e.g., located at) two adjacent first areas 11. For example, the connecting line in the second area 12 may be configured to connects the pixel circuits in the two adjacent first areas 11.

Referring back to FIG. 4, the first area 11 may have a first width w1 along the first direction (e.g., the x direction or the −x direction) and the plurality of first areas 11 may be spaced and/or apart (e.g., spaced apart or separated) from each other by a first pitch p1 along the first direction (e.g., the x direction or the −x direction). For example, the first areas 11 adjacent to each other based on the first direction (e.g., the x direction or the −x direction) may be arranged by the first pitch p1. Here, a “pitch” may be different from an “interval” between the adjacent first areas 11 and may be a concept including a width of the first area 11. For example, the first pitch p1 may denote a shortest distance connecting centers of the adjacent first areas 11 in a straight line, based on a virtual line in the first direction (e.g., the x direction or the −x direction).

According to one or more embodiments, a distance ratio of the first width w1 of the first area 11 in the first direction (e.g., the x direction or the −x direction) to the first pitch p1 between the adjacent first areas 11 may be about 0.2 to about 0.65. For example, if (e.g., when) the first pitch p1 between the first areas 11 may be a denominator and the first width w1 of the first area 11 may be a numerator, a value of the first width w1/the first pitch p1 may satisfy about 0.2 to about 0.65.

In the stretchable display device 1 (FIGS. 2A to 2E), if (e.g., when) the area of the first area 11 arranged in (e.g., located at) the pixel unit PU increases (e.g., if (e.g., when) resolution increases), a width (or the area) of the second area 12 directly contributing to elongation may be decreased. Thus, in the display device 1 (FIGS. 2A to 2E) according to one or more embodiments of the present disclosure, a display device in which a resolution may be increased while an elongation is secured may be implemented by ensuring that the distance ratio of the first width w1 of the first area 11 in an elongation direction to the first pitch p1 between the adjacent first areas 11 satisfies about 0.2 to about 0.65.

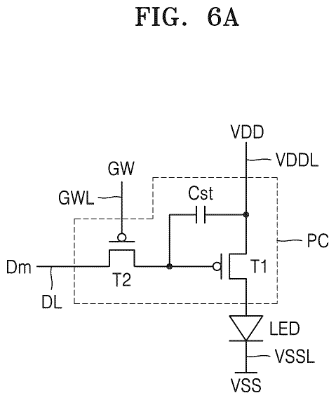

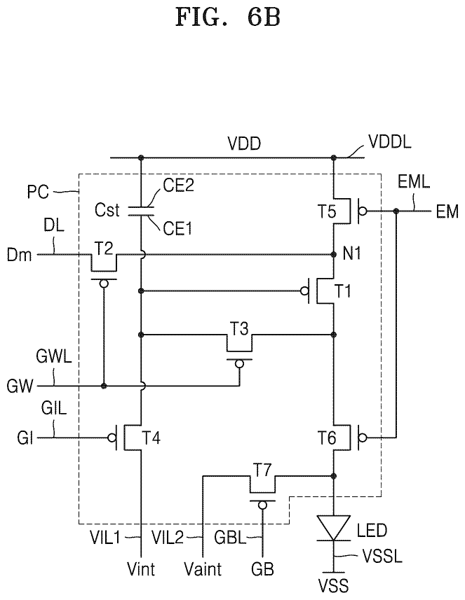

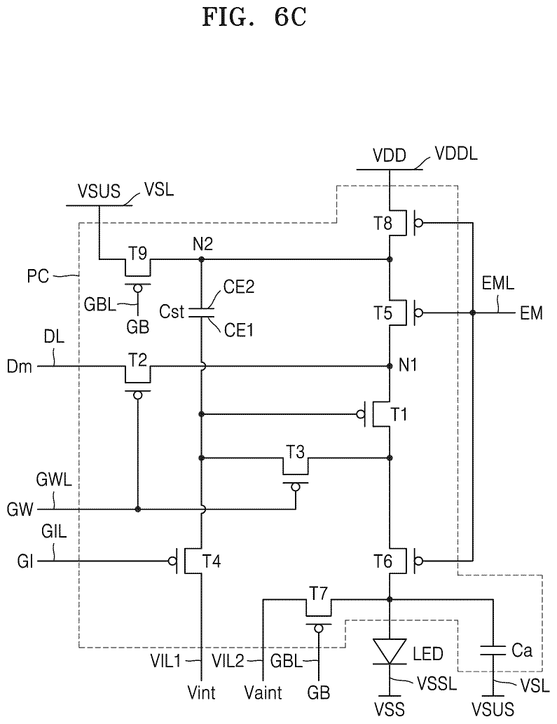

FIGS. 6A to 6C are each an equivalent circuit diagram of a pixel of a display device, according to one or more embodiments of the present disclosure.

Referring to FIG. 6A, a light-emitting diode LED corresponding to a pixel may be electrically connected to the pixel circuit PC, and the pixel circuit PC may include a first transistor T1, a second transistor T2, and/or a storage capacitor Cst. The pixel circuit PC may be electrically connected to a signal line and a voltage line. The signal line may include a scan signal line GWL and a data line DL, and the voltage line may include a first voltage line VDDL.

The second transistor T2 may be electrically connected to the scan signal line GWL and the data line DL. The scan signal line GWL may provide a scan signal GW to a gate electrode of the second transistor T2. The second transistor T2 may be to transmit, to the first transistor T1, a data signal Dm input from the data line DL, according to the scan signal GW input from the scan signal line GWL.

The storage capacitor Cst may be electrically connected to the second transistor T2 and the first voltage line VDDL, and store a voltage corresponding to a difference between a voltage received from the second transistor T2 and a first power voltage VDD supplied by the first voltage line VDDL.

The first transistor T1 may be a driving transistor and may control a driving current flowing through the light-emitting diode LED. The first transistor T1 may be connected to the first voltage line VDDL and the storage capacitor Cst. The first transistor T1 may control the driving current flowing through the light-emitting diode LED from the first voltage line VDDL, in response to a value of a voltage stored in the storage capacitor Cst. The light-emitting diode LED may be to emit light of a certain luminance according to the driving current. A first electrode of the light-emitting diode LED may be electrically connected to the first transistor T1, and a second electrode thereof may be electrically connected to a second voltage line VSSL supplying a second power voltage VSS.

In FIG. 6A, the pixel circuit PC includes two transistors and one storage capacitor, but according to one or more other embodiments, the pixel circuit PC may include three or more transistors.

Referring to FIG. 6B, the pixel circuit PC may include the first transistor T1, the second transistor T2, a third transistor T3, a fourth transistor T4, a fifth transistor T5, a sixth transistor T6, a seventh transistor T7, and/or the storage capacitor Cst.

The pixel circuit PC may be electrically connected to signal lines and voltage lines. The signal lines may include gate lines, such as the scan signal line GWL, a bypass control line GBL, an initialization control line GIL, and an emission control line EML, and the data line DL. The voltage lines may include a first initialization voltage line VIL1, a second initialization voltage line VIL2, and/or the first voltage line VDDL.

The first voltage line VDDL may be to transmit the first power voltage VDD to the first transistor T1. The first initialization voltage line VIL1 may be to transmit, to the pixel circuit PC, a first initialization voltage Vint for initializing the first transistor T1. The second initialization voltage line VIL2 may be to transmit, to the pixel circuit PC, a second initialization voltage Vaint for initializing the first electrode of the light-emitting diode LED.

The first transistor T1 may be electrically connected to the first voltage line VDDL via the fifth transistor T5, and electrically connected to the light-emitting diode LED via the sixth transistor T6. The first transistor T1 operates as a driving transistor and supplies a driving current to the light-emitting diode LED by receiving the data signal Dm according to a switching operation of the second transistor T2.

The second transistor T2 may be a data write transistor and electrically connected to the scan signal line GWL and the data line DL. The second transistor T2 may be electrically connected to the first voltage line VDDL via the fifth transistor T5.

The second transistor T2 may be turned on according to the scan signal GW received through the scan signal line GWL to perform a switching operation of transmitting the data signal Dm transmitted to the data line DL, to a first node N1.

The third transistor T3 may be electrically connected to the scan signal line GWL and electrically connected to the light-emitting diode LED via the sixth transistor T6. The third transistor T3 may be turned on according to the scan signal GW received through the scan signal line GWL and diode-connect the first transistor T1.

The fourth transistor T4 may be a first initialization transistor and may be electrically connected to the initialization control line GIL and the first initialization voltage line VIL1. The fourth transistor T4 may be turned on according to an initialization control signal GI received through the initialization control line GIL to initialize a voltage of the gate electrode of the first transistor T1 by transmitting the first initialization voltage Vint from the first initialization voltage line VIL1 to the gate electrode of the first transistor T1. The initialization control signal GI may correspond to a scan signal from another pixel circuit arranged in a previous row of the corresponding pixel circuit PC.

The fifth transistor T5 may be an operation control transistor, and the sixth transistor T6 may be an emission control transistor. The fifth transistor T5 and the sixth transistor T6 may be electrically connected to the emission control line EML and concurrently (e.g., simultaneously) turned on according to an emission control signal EM received through the emission control line EML, thereby forming/providing a current path for the driving current to flow in a direction from the first voltage line VDDL to the light-emitting diode LED. A first electrode of the light-emitting diode LED may be electrically connected to the first transistor T1 via the sixth transistor T6, and a second electrode thereof may be electrically connected to the second voltage line VSSL supplying the second power voltage VSS.

The seventh transistor T7 may be a second initialization transistor and may be electrically connected to the bypass control line GBL, the second initialization voltage line VIL2, and the sixth transistor T6. The seventh transistor T7 may be turned on according to a bypass control signal GB received through the bypass control line GBL, and may initialize the first electrode of the light-emitting diode LED by transmitting the second initialization voltage Vaint from the second initialization voltage line VIL2 to the first electrode of the light-emitting diode LED.

The storage capacitor Cst may include a first electrode CE1 and a second electrode CE2. The first electrode CE1 may be electrically connected to the gate electrode of the first transistor T1 and the second electrode CE2 may be electrically connected to the first voltage line VDDL. The storage capacitor Cst may maintain a voltage applied to the gate electrode of the first transistor T1 by storing and maintaining a voltage corresponding to a difference between opposite end voltages of the first voltage line VDDL and the gate electrode of the first transistor T1.

Referring to FIG. 6C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and/or an auxiliary capacitor Ca.

The pixel circuit PC may be electrically connected to signal lines and voltage lines. The signal lines may include gate lines, such as the scan signal line GWL, the bypass control line GBL, the initialization control line GIL, and the emission control line EML, and/or the data line DL. The voltage lines may include the first initialization voltage line VIL1, the second initialization voltage line VIL2, a sustain voltage line VSL, and/or the first voltage line VDDL.

The first voltage line VDDL may be to transmit the first power voltage VDD to the first transistor T1. The first initialization voltage line VIL1 may be to transmit, to the pixel circuit PC, the first initialization voltage Vint for initializing the first transistor T1. The second initialization voltage line VIL2 may be to transmit, to the pixel circuit PC, the second initialization voltage Vaint for initializing the first electrode of the light-emitting diode LED. The sustain voltage line VSL may provide a sustain voltage VSUS to a second node N2, for example, the second electrode CE2 of the storage capacitor Cst, during an initialization period and a data write period.

The first transistor T1 may be electrically connected to the first voltage line VDDL via the fifth transistor T5 and the eighth transistor T8, and electrically connected to the light-emitting diode LED via the sixth transistor T6. The first transistor T1 may operate as a driving transistor and may supply the driving current to the light-emitting diode LED by receiving the data signal Dm according to a switching operation of the second transistor T2.

The second transistor T2 may be electrically connected to the scan signal line GWL and the data line DL, and electrically connected to the first voltage line VDDL via the fifth transistor T5 and the eighth transistor T8. The second transistor T2 may be turned on according to the scan signal GW received through the scan signal line GWL to perform a switching operation of transmitting the data signal Dm transmitted to the data line DL, to the first node N1.

The third transistor T3 may be electrically connected to the scan signal line GWL and electrically connected to the light-emitting diode LED via the sixth transistor T6. The third transistor T3 may be turned on according to the scan signal GW received through the scan signal line GWL and may compensate for a threshold voltage of the first transistor T1 by diode-connecting the first transistor T1.

The fourth transistor T4 may be connected to the initialization control line GIL and the first initialization voltage line VIL1, and turned on according to the initialization control signal GI received through the initialization control line GIL to transmit the first initialization voltage Vint from the first initialization voltage line VIL1 to the gate electrode of the first transistor T1, thereby initializing a voltage of the gate electrode of the first transistor T1. The initialization control signal GI may correspond to a scan signal from another pixel circuit arranged in a previous row of the corresponding pixel circuit PC.

The fifth transistor T5, the sixth transistor T6, and/or the eighth transistor T8 may be electrically connected to the emission control line EML and concurrently (e.g., simultaneously) turned on according to the emission control signal EM received through the emission control line EML, thereby forming/providing a current path for the driving current to flow in a direction from the first voltage line VDDL to the light-emitting diode LED. The first electrode of the light-emitting diode LED may be electrically connected to the first transistor T1 via the sixth transistor T6, and the second electrode thereof may be electrically connected to the second voltage line VSSL supplying the second power voltage VSS.

The seventh transistor T7 may be the second initialization transistor and may be electrically connected to the bypass control line GBL, the second initialization voltage line VIL2, and/or the sixth transistor T6. The seventh transistor T7 may be turned on according to the bypass control signal GB received through the bypass control line GBL, and may initialize the first electrode of the light-emitting diode LED by transmitting the second initialization voltage Vaint from the second initialization voltage line VIL2 to the first electrode of the light-emitting diode LED.

The ninth transistor T9 may be electrically connected to the bypass control line GBL, the second electrode CE2 of the storage capacitor Cst, and/or the sustain voltage line VSL. The ninth transistor T9 may be turned on according to the bypass control signal GB received through the bypass control line GBL and transmit the sustain voltage VSUS to the second node N2, for example, the second electrode CE2 of the storage capacitor Cst, in the initialization period and the data write period.

The eighth transistor T8 and the ninth transistor T9 may be each electrically connected to the second node N2, for example, the second electrode CE2 of the storage capacitor Cst. According to one or more embodiments, the eighth transistor T8 may be turned off and the ninth transistor T9 may be turned on in the initialization period and the data write period, and the eighth transistor T8 may be turned on and the ninth transistor T9 may be turned off in an emission period.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and/or the ninth transistor T9.

The auxiliary capacitor Ca may be electrically connected to the sixth transistor T6, the sustain voltage line VSL, and/or the first electrode of the light-emitting diode LED. The auxiliary capacitor Ca may store and maintain a voltage corresponding to a voltage difference between the first electrode of the light-emitting diode LED and the sustain voltage line VSL while the seventh transistor T7 and the ninth transistor T9 may be turned on, thereby preventing or reducing an increase in black luminance if (e.g., when) the sixth transistor T6 is turned off.

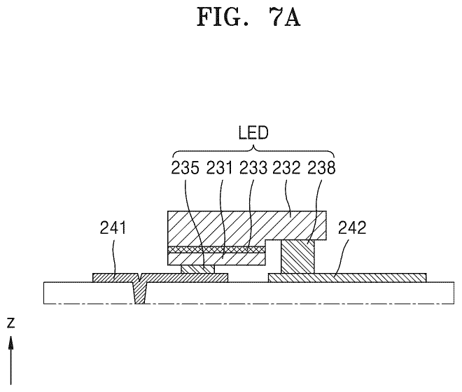

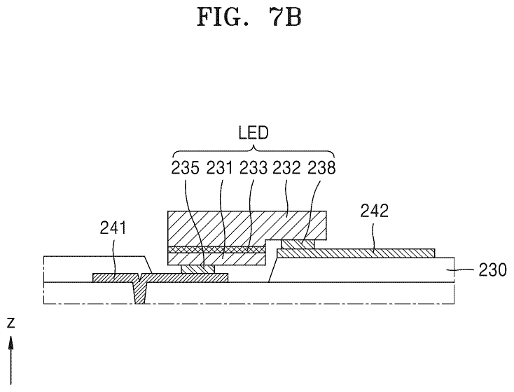

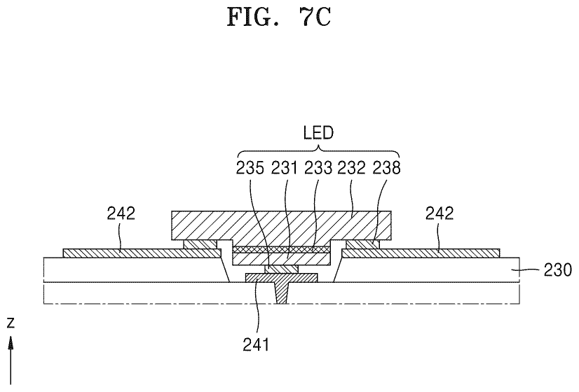

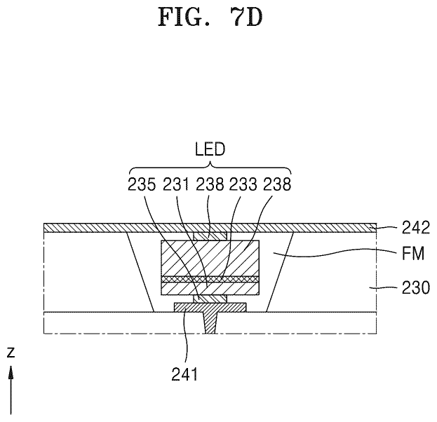

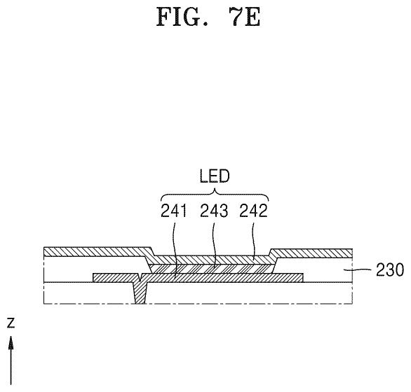

FIGS. 7A to 7E are each a cross-sectional view schematically showing a light-emitting diode of a display device, according to one or more embodiments of the present disclosure.

Referring to FIG. 7A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and/or a second electrode 238 electrically connected to the second semiconductor layer 232. The first electrode 235 and the second electrode 238 of the light-emitting diode LED may be electrically connected to a first electrode pad 241 and a second electrode pad 242, which may be arranged on substantially the same layer, respectively. The second electrode pad 242 may be a portion of the second voltage line VSSL (FIG. 6A) or a conductive layer electrically connected to the second voltage line VSSL (FIG. 6A).

According to one or more embodiments, the first semiconductor layer 231 may include a p-type (kind) semiconductor layer. The p-type (kind) semiconductor layer may be selected from among semiconductor materials having a composition formula of InₓAl_{y}Ga_{1-x-y}N (e.g., 0≤x≤1, 0≤y≤1, and 0≤x+y≤1), for example, GaN, AlN, AlGaN, InGaN, InN, InAlGaN, and/or AlInN, and a p-type (kind) dopant, such as Mg, Zn, Ca, Sr, and/or Ba, may be doped.

The second semiconductor layer 232 may include, for example, an n-type (kind) semiconductor layer. The n-type (kind) semiconductor layer may be selected from among semiconductor materials having a composition formula of InₓAl_{y}Ga_{1-x-y}N (e.g., 0≤x≤1, 0≤y≤1, and 0≤x+y≤1), for example, GaN, AlN, AlGaN, InGaN, InN, InAlGaN, and/or AlInN, and an n-type (kind) dopant, such as Si, Ge, and/or Sn, may be doped.

The intermediate layer 233 may be a region where electrons and holes recombine, and if (e.g., when) the electrons and holes recombine, the intermediate layer 233 may transit to a low energy level and generate light having a corresponding wavelength. The intermediate layer 233 may include, for example, a semiconductor material having a composition formula of InₓAl_{y}Ga_{1-x-y}N (e.g., 0≤x≤1, 0≤y≤1, and 0≤x+y≤1), and may have a single quantum well structure or a multi quantum well (MQW) structure. Also, the intermediate layer 233 may have a quantum wire structure or a quantum dot structure.

In FIG. 7A, the first semiconductor layer 231 may include the p-type (kind) semiconductor layer and the second semiconductor layer 232 may include the n-type (kind) semiconductor layer, but the present disclosure is not limited thereto. According to one or more other embodiments, the first semiconductor layer 231 may include the n-type (kind) semiconductor layer and the second semiconductor layer 232 may include the p-type (kind) semiconductor layer.

In FIG. 7A, the first electrode pad 241 and the second electrode pad 242 may be arranged on substantially the same layer, but the present disclosure is not limited thereto. Referring to FIG. 7B, the first electrode pad 241 and the second electrode pad 242 may be arranged on different layers. For example, a bank layer 230 including an opening overlapping at least a portion of the first electrode pad 241 may be arranged on the first electrode pad 241, and the second electrode pad 242 may be arranged on a top surface of the bank layer 230. A structure of the light-emitting diode LED shown in FIG. 7B may be substantially the same as that described above with reference to FIG. 7A.

According to one or more other embodiments, as shown in FIG. 7C, the second electrode pad 242 may be arranged on opposite sides based on the first electrode pad 241 in cross-sectional view. The bank layer 230 may include an opening overlapping at least a portion of the first electrode pad 241, and the second electrode pad 242 may be arranged around the opening of the bank layer 230. According to one or more embodiments, in plan view, the second electrode pad 242 may have a closed loop shape entirely around (e.g., surrounding) the opening of the bank layer 230 and/or the first electrode pad 241. A structure of the light-emitting diode LED shown in FIG. 7C may be substantially the same as that described above with reference to FIG. 7A.

In FIGS. 7A to 7C, the first electrode 235 and the second electrode 238 of the light-emitting diode LED may face substantially the same direction (e.g., a downward direction, a −z direction), but the present disclosure is not limited thereto. As shown in FIG. 7D, the first electrode 235 and the second electrode 238 of the light-emitting diode LED may face opposite directions.

The bank layer 230 may include an opening exposing at least a portion of the first electrode pad 241, and a thickness of the bank layer 230 may be substantially the same as a thickness of the light-emitting diode LED. The opening of the bank layer 230 may be filled with a filling material FM, and the second electrode pad 242 may be arranged on the top surface of the bank layer 230 to be electrically connected to (e.g., in contact with) the second electrode 238 of the light-emitting diode LED. The filling material FM may be an organic material having insulating properties.

In FIGS. 7A to 7D, the light-emitting diode LED may include the inorganic light-emitting diode including the inorganic material, but the present disclosure is not limited thereto. Referring to FIG. 7E, the light-emitting diode LED may include an organic light-emitting diode including an organic material. For example, the light-emitting diode LED may include the first electrode pad 241 (or a first electrode), an organic emission layer 243 overlapping the first electrode pad 241 through the opening of the bank layer 230 arranged on the first electrode pad 241, and the second electrode pad 242 (or a second electrode) on the organic emission layer 243. The second electrode pad 242 may be shared between the light-emitting diodes LED. For example, the second electrode pad 242 of any one of the light-emitting diodes LED may be integrally connected to the second electrode pad 242 of another light-emitting diode LED.

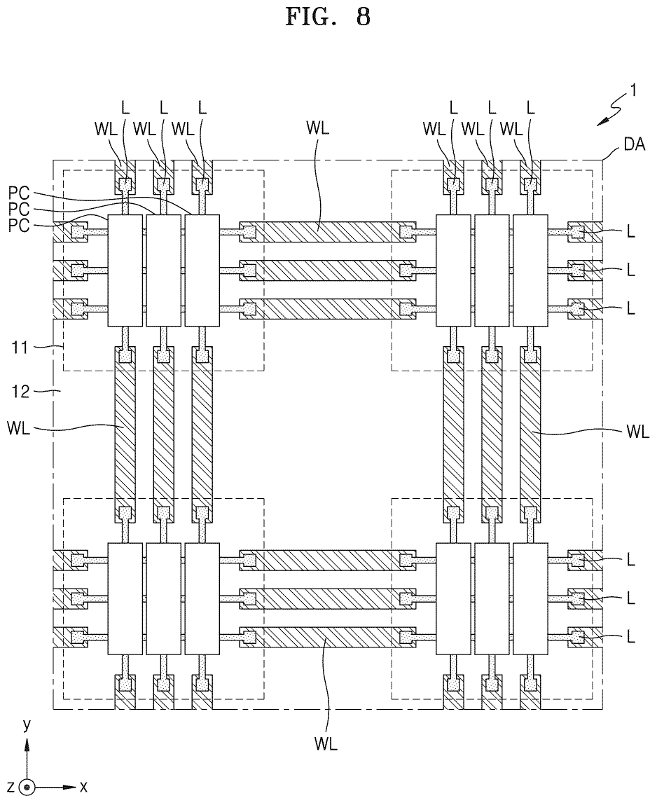

FIG. 8 is a plan view schematically showing a portion of the display area DA of the display device 1, according to one or more embodiments of the present disclosure.

FIG. 8 illustrates conductive lines (hereinafter, referred to as lines L) electrically connected to the pixel circuits PC arranged in (e.g., located at) the display area DA. The pixel circuits PC arranged in (e.g., located at) each first area 11 shown in FIG. 8 may be electrically connected to light-emitting diodes corresponding to the pixels PXr, PXg, and PXb described with reference to FIG. 4.

Referring to FIG. 8, the pixel circuit PC for driving the light-emitting diode of each pixel may be arranged in (e.g., located at) the first area 11. For example, FIG. 8 illustrates three pixel circuits PC arranged in (e.g., located at) the first area 11. Each pixel circuit PC may include a transistor and a capacitor like the pixel circuit PC described above with reference to FIGS. 6A to 6C.

The first area 11 may have a smaller elongation than the second area 12. Accordingly, if (e.g., when) the display device 1 may be stretched, the first area 11 may be deformed less than the second area 12 or may not be deformed. As described above, the first area 11 may be referred to as a low deformation area (or a low deformation portion) or a non-deformation area (or a non-deformation portion). The first area 11 may be an area where light-emitting diodes are arranged, and may be referred to as a pixel area or an emission area.

The second area 12 may surround the first area 11 and have a larger elongation than the first area 11. The second area 12 may be an area that may be mainly deformed according to stretching of the display device. The second area 12 may be arranged between the plurality of first areas 11 and may be referred to as a connecting portion that connects the first areas 11. The second area 12 may be referred to as a main deformation area (or a main deformation portion) or a high deformation area (or a high deformation portion). The second area 12 may be an area where a light-emitting diode is not arranged among the display area and may be referred to as a non-pixel area or a non-emission area.

The lines L electrically connected to the pixel circuit PC may be arranged in (e.g., located at) the display area DA. According to one or more embodiments, FIG. 8 illustrates the lines L extending in the first direction (e.g., the x direction or the −x direction) and the lines L extending in the second direction (e.g., the y direction or the −y direction) being electrically connected to the pixel circuits PC. Each of the lines L may be electrically connected to the pixel circuit PC through a contact hole.

One line L arranged in (e.g., located at) the first area 11 may be electrically connected to one line L arranged in (e.g., located at) the adjacent first area 11 through a connecting line WL. The lines L may include a voltage line and/or a signal line. The lines L may include a gate line providing a gate signal to a gate electrode of a transistor, a data line, and/or a voltage line. According to one or more embodiments, the lines L extending in the first direction (e.g., the x direction or the −x direction) may include gate lines (e.g., the scan signal line GWL, the bypass control line GBL, the initialization control line GIL, and/or the emission control line EML) and/or the second voltage line VSSL described above with reference to FIGS. 6A to 6C. The lines L extending in the second direction (e.g., the y direction or the −y direction) may include the data line DL, the first initialization voltage line VIL1, the second initialization voltage line VIL2, the sustain voltage line VSL, and/or the first voltage line VDDL described above with reference to FIGS. 6A to 6C.

The connecting line WL arranged in (e.g., located at) the second area 12 may be stretched better than the lines L arranged in (e.g., located at) the first area 11.

For example, the connecting line WL may be stretched longer and/or wider than the lines L. An elongation of each connecting line WL may be greater than an elongation of each line L.

The lines L may each include one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the lines L may each include a single layer or plurality of layers including the above-described metal. According to one or more embodiments, the lines L may each include a metal thin film including a triple layer of a Ti/Al/Ti structure (e.g., a triple layer including a layer of Ti, a layer of Al, and a layer of Ti).

The connecting line WL may include a liquid metal and/or a conductive composite material including a metal nanostructure, elastic polymer, and/or elastomer. Accordingly, if (e.g., when) the display device 1 (FIG. 1) may be stretched, the connecting line WL and the second area 12 may be highly deformed.

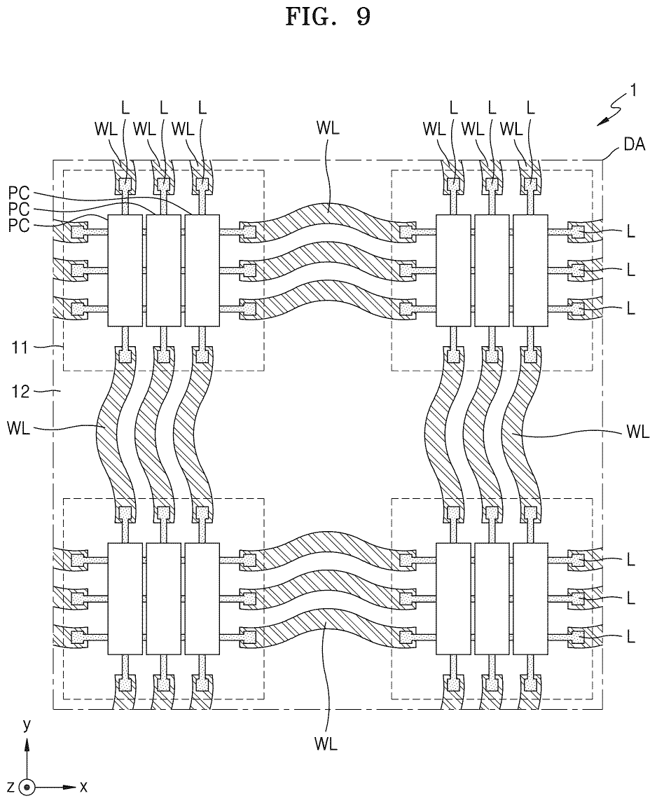

FIG. 9 is a plan view schematically showing a portion of the display area DA of the display device 1, according to one or more embodiments of the present disclosure.

In the embodiment described with reference to FIG. 8, the connecting line WL may be a straight line in plan view, but the present disclosure is not limited thereto. As shown in FIG. 9, the connecting line WL may have a shape other than a straight line in plan view. The display device 1 according to the embodiment of FIG. 9 differs from the embodiment described above with reference to FIG. 8 in the shape of the connecting line WL in plan view, while other configurations may each independently be substantially the same as the embodiment of FIG. 8. Hereinafter, redundant descriptions will not be provided and differences will be mainly described.

Referring to FIG. 9, each connecting line WL may have a serpentine shape in plan view. For example, each connecting line WL may have a wave shape with two or more inflection points. If (e.g., when) the connecting line WL has a serpentine shape, deformation of damage to the connecting line WL may be effectively prevented or reduced if (e.g., when) the second area 12 may be stretched. FIG. 9 illustrates the connecting line WL having a gentle C-shape in plan view, but according to one or more other embodiments, the connecting line WL may have a wave shape, such as an S-shape, in plan view.

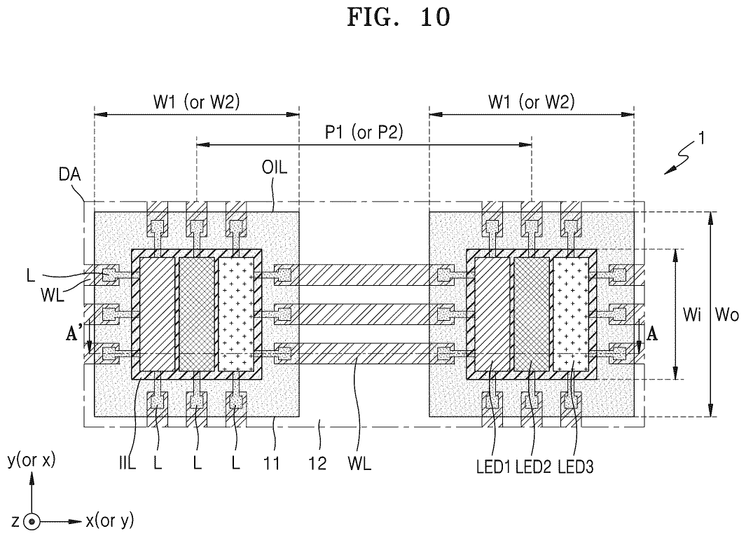

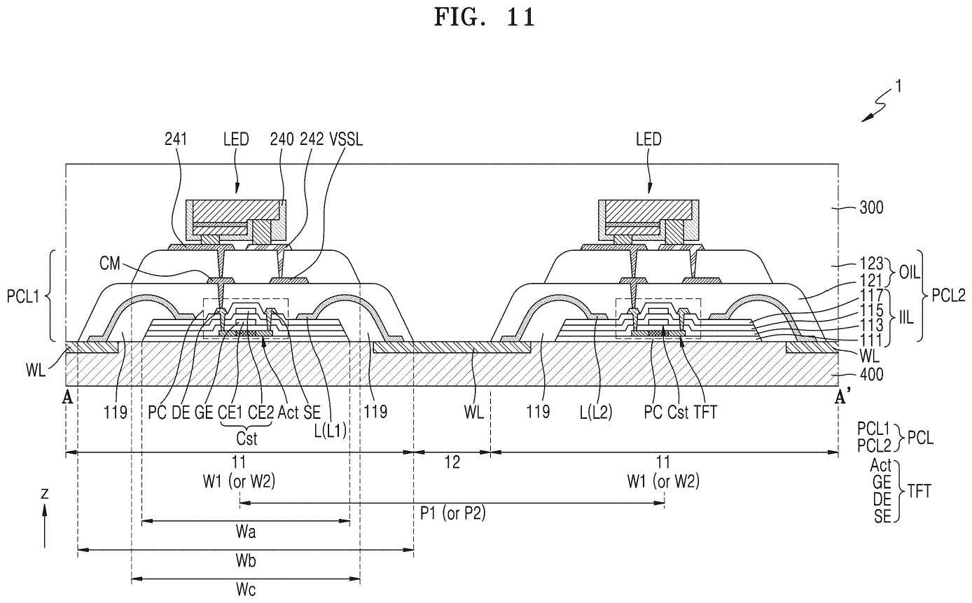

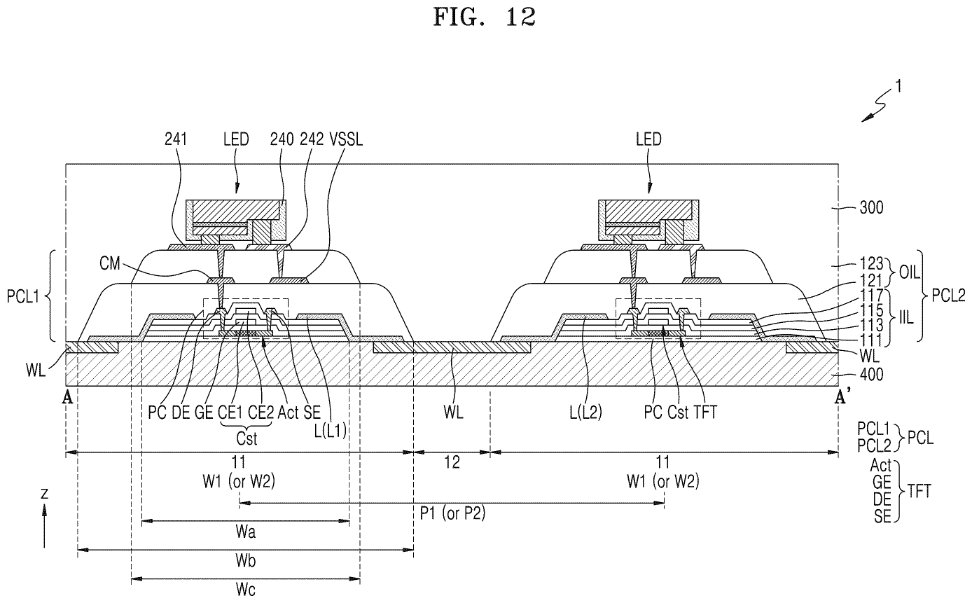

FIG. 10 is a plan view showing an excerpt of a portion of a display device, according to one or more embodiments of the present disclosure, and FIG. 11 is a cross-sectional view taken along a line A-A′ of FIG. 10. FIGS. 12 to 14 are cross-sectional views showing portions of a part (e.g., excerpts of a portion) of a display device, according to one or more embodiments of the present disclosure, and illustrate modified examples of FIG. 11.

Referring to FIG. 10, light-emitting diodes, e.g., the first, second, and third light-emitting diodes LED1, LED2, and LED3 (FIG. 10), arranged in (e.g., located at) the first area 11 may each be electrically connected to the pixel circuits PC (FIG. 5) described with reference to FIG. 5. The inorganic insulating stack IIL and the organic insulating layer OIL may be arranged in (e.g., located at) the first area 11. The first, second, and third light-emitting diodes LED1, LED2, and LED3 may be arranged on the inorganic insulating stack IIL and the organic insulating layer OIL.

Referring to FIG. 10, as described above with reference to FIGS. 4 and 5, the display device 1 may include the first areas 11 and the second area 12 between the first areas 11. As will be described in more detail with reference to FIG. 11, components of the display device 1 may be arranged on the base layer 400, and thus, the display device 1 including the first area 11 and the second area 12 may correspond to the base layer 400 including the first area 11 and the second area 12.

Referring to FIG. 11, the display device 1 may include a pixel circuit layer PCL arranged in (e.g., located at) each of the two adjacent first areas 11, and the light-emitting diode LED on the pixel circuit layer PCL. Also, in FIG. 11, one light-emitting diode LED from among the first, second, and third light-emitting diodes LED1, LED2, and LED3 shown in FIG. 10 is illustrated for convenience of description, and the light-emitting diode LED shown in FIG. 11 may correspond to one selected from among the first, second, and third light-emitting diodes LED1, LED2, and LED3 shown in FIG. 10.

Each pixel circuit layer PCL may include the inorganic insulating stack IIL, the pixel circuit PC, and/or the organic insulating layer OIL. Hereinafter, for convenience of description, one selected from among the pixel circuit layers PCL respectively arranged in (e.g., located at) the two adjacent first areas 11 will be referred to as a first pixel circuit layer PCL1, and the other one will be referred to as a second pixel circuit layer PCL2.

The first pixel circuit layer PCL1 and the second pixel circuit layer PCL2 may each be arranged on the base layer 400. The first pixel circuit layer PCL1 and the second pixel circuit layer PCL2 may each be arranged on a first surface (e.g., a top surface) of the base layer 400.

The base layer 400 may be to absorb stress generated if (e.g., when) the display device 1 may be stretched. The base layer 400 may include a stretchable material, e.g., an stretchable polymer resin. According to one or more embodiments, the base layer 400 may include an elastomer (e.g., an elastic polymer). The elastomer may include an organic elastomer, an organic/inorganic elastomer, and/or a combination thereof. The base layer 400 may include one selected from among thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

The first pixel circuit layer PCL1 and the second pixel circuit layer PCL2 may each include the inorganic insulating stack IIL, the pixel circuit PC, and/or the organic insulating layer OIL. The inorganic insulating stack IIL may include a buffer layer 111, a gate insulating layer 113, a first interlayer insulating layer 115, and/or a second interlayer insulating layer 117. The organic insulating layer OIL may include a first organic insulating layer 121 and/or a second organic insulating layer 123.

The inorganic insulating stack IIL and the organic insulating layer OL may each have an isolated shape as shown in FIG. 10. The inorganic insulating stack IIL and the organic insulating layer OL may each be arranged in (e.g., located at) the first area 11. The second area 12 where the inorganic insulating stack IIL and the organic insulating layer OL do not exist may be relatively suitably deformed.

The first area 11 may be defined as an area if (e.g., when) the inorganic insulating stack IIL and the organic insulating layer OL may be projected along a direction perpendicular to the base layer 400. According to one or more embodiments, if (e.g., when) a width Wi of the inorganic insulating stack IIL may be smaller than a width Wo of the organic insulating layer OL, the width Wo of the organic insulating layer OL may correspond to a width of the first area 11.

The first pixel circuit layer PCL1 and the second pixel circuit layer PCL2 may be spaced and/or apart (e.g., spaced apart or separated) from each other. The first pixel circuit layer PCL1 and the second pixel circuit layer PCL2 being spaced and/or apart (e.g., spaced apart or separated) from each other may indicate that the inorganic insulating stack IIL, the pixel circuit PC, and the organic insulating layer OIL of the first pixel circuit layer PCL1 may be respectively spaced and/or apart (e.g., spaced apart or separated) from the inorganic insulating stack IIL, the pixel circuit PC, and the organic insulating layer OIL of the second pixel circuit layer PCL2.

The inorganic insulating stack IIL may be arranged in (e.g., located at) the first area 11 and not arranged in (e.g., located at) the second area 12. The inorganic insulating stacks IIL respectively arranged in (e.g., located at) the first areas 11 may be spaced and/or apart (e.g., spaced apart or separated) from each other in plan view. For example, the buffer layer 111, the gate insulating layer 113, the first interlayer insulating layer 115, and the second interlayer insulating layer 117 of the first pixel circuit layer PCL1 may be respectively separated and spaced and/or apart (e.g., spaced apart or separated) from the buffer layer 111, the gate insulating layer 113, the first interlayer insulating layer 115, and the second interlayer insulating layer 117 of the second pixel circuit layer PCL2.

Similarly, the organic insulating layer OIL may be arranged in (e.g., located at) the first area 11 and not arranged in (e.g., located at) the second area 12. For example, the first organic insulating layer 121 and the second organic insulating layer 123 of the first pixel circuit layer PCL1 may be respectively separated and spaced and/or apart (e.g., spaced apart or separated) from the first organic insulating layer 121 and the second organic insulating layer 123 of the second pixel circuit layer PCL2.

As shown in FIG. 11, the buffer layer 111 may be arranged on the base layer 400 and the pixel circuit PC may be arranged on the buffer layer 111. The buffer layer 111 may include an inorganic insulating material such as silicon oxide, silicon nitride, and/or silicon oxynitride.

A thin-film transistor TFT of the pixel circuit PC may include a semiconductor layer Act, a gate electrode GE, a source electrode SE, and/or a drain electrode DE. FIG. 11 illustrates a top-gate type (kind) in which the gate electrode GE may be arranged on the semiconductor layer Act with the gate insulating layer 113 therebetween, but according to one or more other embodiments, the thin-film transistor TFT may be a bottom-gate type (kind).

The semiconductor layer Act may include polysilicon. In one or more embodiments, the semiconductor layer Act may include amorphous silicon, an oxide semiconductor, and/or an organic semiconductor. The gate electrode GE may include a metal thin-film including a low-resistance metal material. The gate electrode GE may include a conductive material including one selected from among molybdenum (Mo), aluminum (AI), copper (Cu), and titanium (Ti), and may be formed/provided in a multi-layer or single layer including the conductive material. For example, the gate electrode GE may include a metal thin-film including a triple layer of a Ti/Al/Ti structure (e.g., a triple layer including a layer of Ti, a layer of Al, and a layer of Ti).

The gate insulating layer 113 between the semiconductor layer Act and the gate electrode GE may include an inorganic insulating material such as silicon oxide, silicon nitride, silicon oxynitride, aluminum oxide, and/or titanium oxide. The gate insulating layer 113 may be a single layer or multi-layer including the material described above.

The source electrode SE and the drain electrode DE may be located on substantially the same layer, e.g., on the second interlayer insulating layer 117, and include substantially the same material. The source electrode SE and the drain electrode DE may include a metal thin-film including a low-resistance metal material.

The source electrode SE and the drain electrode DE may be respectively connected to a source region and a drain region of the semiconductor layer Act.

The source electrode SE and the drain electrode DE may include a conductive material including one selected from among molybdenum (Mo), aluminum (Al), copper (Cu), and titanium (Ti), and may be formed/provided in a multi-layer or single layer including the conductive material. For example, similar to the gate electrode GE, the source electrode SE and the drain electrode DE may include a metal thin-film including a triple layer of a Ti/Al/Ti structure (e.g., a triple layer including a layer of Ti, a layer of Al, and a layer of Ti). The second interlayer insulating layer 117 may include an inorganic insulating material such as silicon oxide, silicon nitride, silicon oxynitride, aluminum oxide, and/or titanium oxide, and may be a single layer or multi-layer including the material described above.

The storage capacitor Cst may include the first electrode CE1 and the second electrode CE2, which overlap each other with the first interlayer insulating layer 115 therebetween. The storage capacitor Cst may overlap the thin-film transistor TFT.

For example, FIG. 11 illustrates that the gate electrode GE of the thin-film transistor TFT may be the first electrode CE1 of the storage capacitor Cst. According to one or more other embodiments, the storage capacitor Cst may not overlap the thin-film transistor TFT. The storage capacitor Cst may be covered by the second interlayer insulating layer 117.

The first interlayer insulating layer 115 may be arranged between the gate insulating layer 113 and the second interlayer insulating layer 117. The first interlayer insulating layer 115 and the second interlayer insulating layer 117 may each include an inorganic insulating material such as silicon oxide, silicon nitride, silicon oxynitride, aluminum oxide, and/or titanium oxide, and may each be a single layer or multi-layer including the material described above.

The second electrode CE2 of the storage capacitor Cst may include a conductive material and may be formed/provided in a single layer or a multi-layer. The second electrode CE2 may include a metal thin-film including a low-resistance metal material. The second electrode CE2 may include a conductive material including one selected from among molybdenum (Mo), aluminum (Al), copper (Cu), and titanium (Ti), and may be formed/provided in a multi-layer or single layer including the conductive material. For example, the second electrode CE2 may include a metal thin-film including a triple layer of a Ti/Al/Ti structure (e.g., a triple layer including a layer of Ti, a layer of Al, and a layer of Ti).

The first organic insulating layer 121 may be arranged on the second interlayer insulating layer 117. The second organic insulating layer 123 may be arranged on the first organic insulating layer 121. A connecting electrode CM and the second voltage line VSSL may be arranged on the first organic insulating layer 121. The connecting electrode CM may electrically connect the pixel circuit PC to the first electrode pad 241. The second voltage line VSSL may be electrically connected to the second electrode pad 242.

The connecting electrode CM and the second voltage line VSSL may include a metal thin-film including a low-resistance metal material. The connecting electrode CM and the second voltage line VSSL may include a conductive material including one selected from among molybdenum (Mo), aluminum (AI), copper (Cu), and titanium (Ti), and may be formed/provided in a multi-layer or single layer including the conductive material. For example, the connecting electrode CM and the second voltage line VSSL may include a metal thin film including a triple layer of a Ti/Al/Ti structure (e.g., a triple layer including a layer of Ti, a layer of Al, and a layer of Ti).

The first electrode pad 241 and the second electrode pad 242 may be arranged on the second organic insulating layer 123. The first electrode pad 241 may be electrically connected to the thin-film transistor TFT through the connecting electrode CM between the first organic insulating layer 121 and the second organic insulating layer 123.

The light-emitting diode LED on the first electrode pad 241 and the second electrode pad 242 may be substantially the same as the light-emitting diode LED described above with reference to FIG. 7A. According to one or more other embodiments, the light-emitting diode LED may have a structure as shown in FIGS. 7B to 7E. One surface of the light-emitting diode LED may include an organic insulating material or may be covered by a protecting layer 240 including an inorganic insulating material and an organic insulating material.

According to one or more embodiments, the organic insulating layer OIL may further include a third organic insulating layer 119 arranged to cover a side surface of the inorganic insulating stack IIL. The third organic insulating layer 119 may have a closed loop shape in plan view to cover the side surface of the inorganic insulating stack IIL. For example, the third organic insulating layer 119 may have a shape of a frame in plan view.

In one or more embodiments, as shown in FIG. 11, a top surface of the third organic insulating layer 119 may convexly protrude towards a third direction (e.g., a +z direction). According to one or more other embodiments, the top surface of the third organic insulating layer 119 may be approximately flat.

The line L described with reference to FIG. 10 may be electrically connected to the pixel circuit PC of the pixel circuit layer PCL. For example, FIG. 11 illustrates, from among the lines L of FIG. 10, a line (hereinafter, referred to as a first line L1) arranged in (e.g., located at) one first area 11 being electrically connected to the pixel circuit PC of the first pixel circuit layer PCL1, and a line (hereinafter, referred to as a second line L2) arranged in (e.g., located at) another first area 11 being electrically connected to the pixel circuit PC of the second pixel circuit layer PCL2.

The first and second lines L1 and L2 of FIG. 11 may be signal lines and/or voltage lines. For example, the first and second lines L1 and L2 may include the gate line, the data line DL, the first voltage line VDDL, the second voltage line VSSL, the first initialization voltage line VIL1, the second initialization voltage line VIL2, the sustain voltage line VSL, the first voltage line VDDL, and/or the second voltage line VSSL described with reference to FIGS. 6A to 6C.

The connecting line WL may be arranged in (e.g., located at) the second area 12. The connecting line WL may be to extend to a portion of the first area 11 across the second area 12. For example, opposite end portions of the connecting line WL may overlap the first area 11. The connecting line WL may be arranged on the base layer 400.

The connecting line WL may include a conductive stretchable material that may be both (e.g., simultaneously) conductive and stretchable. For example, the connecting line WL may include a metal nanostructure and/or an elastic polymer. The metal nanostructure may include at least one selected from among an Ag nanoparticle, an Ag nanoflake, and an Ag nanowire. The elastic polymer may include at least one selected from among polydimethylsiloxane (PDMS), polyurethane (PU), and ecoflex.

According to one or more embodiments, an elongation of the conductive stretchable material included in the connecting line WL may be restricted to about 200% or less. In more detail, the elongation of the conductive stretchable material included in the connecting line WL may be more than 0% but not more than 200%. If (e.g., when) the elongation of the conductive stretchable material included in the connecting line WL may be more than 200%, conductivity may deteriorate or may be destabilized due to a change in resistance of the connecting line WL.

Each of the first line L1 and the second line L2 may be arranged on the second interlayer insulating layer 117 and may be to extend towards the connecting line WL. For example, each of the first line L1 and the second line L2 may be to extend towards the connecting line WL across a top surface of the corresponding third organic insulating layer 119. A portion of each of the first line L1 and the second line L2 may be arranged between the third organic insulating layer 119 and the first organic insulating layer 121.

An end portion of the first line L1 and an end portion of the second line L2 may be arranged on the second interlayer insulating layer 117. Another end portion of the first line L1 and another end portion of the second line L2 may be arranged on the connecting line WL that may be arranged on the base layer 400, to be electrically connected to the connecting line WL.

In more detail, a first connection point (e.g., the other end portion of the first line L1) between the first line L1 and the connecting line WL, and a second connection point (e.g., the other end portion of the second line L2) between the second line L2 and the connecting line WL may be arranged between the inorganic insulating stack IIL of the first pixel circuit layer PCL1 and the inorganic insulating stack IIL of the second pixel circuit layer PCL2. The first connection point between the first line L1 and the connecting line WL may be a direct contact area between the first line L1 and the connecting line WL and does not overlap the inorganic insulating stack IIL of the first pixel circuit layer PCL1. The second connection point between the second line L2 and the connecting line WL may be a direct contact area between the second line L2 and the connecting line WL and does not overlap the inorganic insulating stack IIL of the second pixel circuit layer PCL2.

The first organic insulating layer 121 corresponding to the first pixel circuit layer PCL1 may be to extend towards the first connection point between the first line L1 and the connecting line WL, across a side surface of the inorganic insulating stack IIL. The first organic insulating layer 121 corresponding to the second pixel circuit layer PCL2 may be to extend towards the second connection point between the second line L2 and the connecting line WL, across the side surface of the inorganic insulating stack IIL. For example, the first connection point between the first line L1 and the connecting line WL may be covered by the first organic insulating layer 121 corresponding to the first pixel circuit layer PCL1, and the second connection point between the second line L2 and the connecting line WL may be covered by the first organic insulating layer 121 corresponding to the second pixel circuit layer PCL2.

The light-emitting diode LED may be arranged on the pixel circuit layer PCL. For example, the light-emitting diode LED electrically connected to the pixel circuit PC of the first pixel circuit layer PCL1 may be arranged on the corresponding first pixel circuit layer PCL1, and the light-emitting diode LED electrically connected to the pixel circuit PC of the second pixel circuit layer PCL2 may be arranged on the corresponding second pixel circuit layer PCL2. One surface of each light-emitting diode LED may be covered by the protecting layer 240. The protecting layer 240 may include an organic insulating material such as polyimide.

The protecting layer 300 may be arranged on the light-emitting diode LED and the connecting line WL. The protecting layer 300 may cover the light-emitting diode LED and the connecting line WL.

The protecting layer 300 may be to absorb stress that may be transferred to the light-emitting diode LED and the connecting line WL if (e.g., when) the display device 1 may be stretched, and may flatten a top surface of the display device 1. The protecting layer 300 may include elastic polymer. For example, the protecting layer 300 may include at least one selected from among thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

The protecting layer 300 may be in direct contact with a portion of a top surface of the connecting line WL and in direct contact with a portion of a top surface of the base layer 400 (e.g., a portion of a top surface of the base layer 400 between the connecting lines WL shown in FIG. 9). According to one or more embodiments, if (e.g., when) a material of the protecting layer 300 and a material of the base layer 400 may each independently be substantially the same, adhesion between the protecting layer 300 and the base layer 400 may be increased, and thus, sealing of the display device may be further effectively maintained.

Referring to FIG. 12, the first line L1 may be to extend over to the connecting line WL while in contact with a side surface of the corresponding inorganic insulating stack IIL, and the second line L2 may be to extend over to the connecting line WL while in contact with a side surface of the corresponding inorganic insulating stack IIL. The first organic insulating layer 121 of the first pixel circuit layer PCL1 may have a greater width than the inorganic insulating stack IIL. The first organic insulating layer 121 may cover the first connection point between the first line L1 and the connecting line WL. Similarly, the first organic insulating layer 121 of the second pixel circuit layer PCL2 may have a greater width than the inorganic insulating stack IIL. The first organic insulating layer 121 may cover the second connection point between the second line L2 and the connecting line WL.

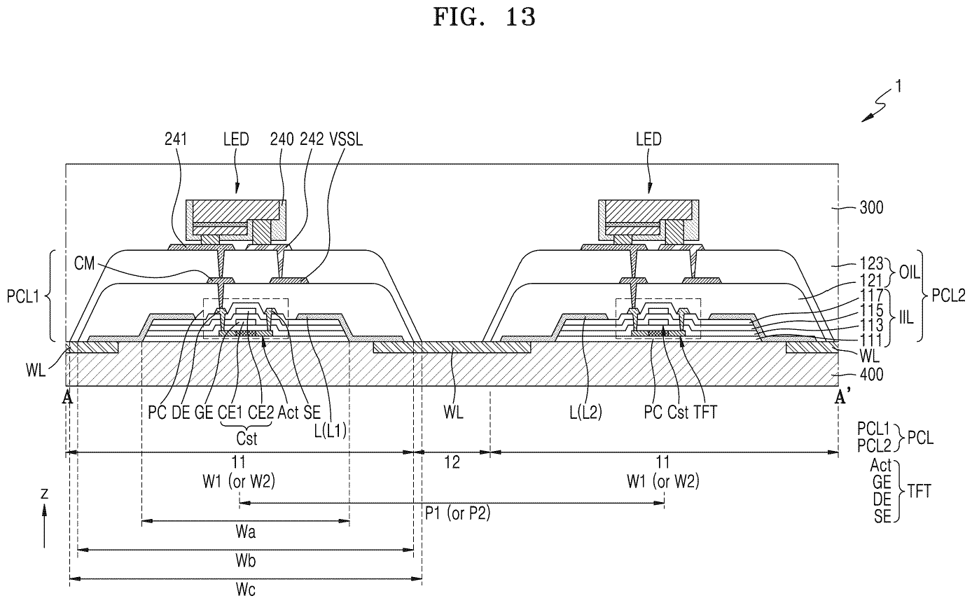

The second organic insulating layer 123 may be to extend towards the connecting line WL while not covering the side surface of the first organic insulating layer 121 as shown in FIG. 12 or may be to extend towards the connecting line WL while covering the side surface of the first organic insulating layer 121 as shown in FIG. 13. According to one or more embodiments, as shown in FIG. 12, the side surface of the second organic insulating layer 123 may be in contact with the top surface of the first organic insulating layer 121. According to one or more other embodiments, as shown in FIG. 13, the second organic insulating layer 123 may be in contact with a portion of the top surface of the connecting line WL while covering the side surface of the first organic insulating layer 121.

Referring to FIGS. 10 to 13, a “width” of the first area 11 may be based on a layer having the widest width based on an elongation direction. In FIGS. 11 to 13 illustrating cross-sectional views taken along the line A-A′ of FIG. 10, if (e.g., when) it may be assumed that elongation occurs in the first direction (e.g., the x direction or the −x direction), the first width W1 of the first area 11 in the first direction (e.g., the x direction or the −x direction) may be based on a layer having the widest width among layers including the inorganic insulating stack IIL and the organic insulating layer OIL. In more detail, if (e.g., when) the inorganic insulating stack IIL may be a first layer, the first organic insulating layer 121 may be a second layer, and the second organic insulating layer 123 may be a third layer, the first width W1 of the first area 11 may be based on the widest width among a width Wa of the first layer, a width Wb of the second layer, and a width Wc of the third layer. In FIGS. 11 and 12, the first width W1 of the first area 11 may be based on the width Wb of the first organic insulating layer 121. Also, in FIG. 13, the first width W1 of the first area 11 may be based on the width Wc of the second organic insulating layer 123.

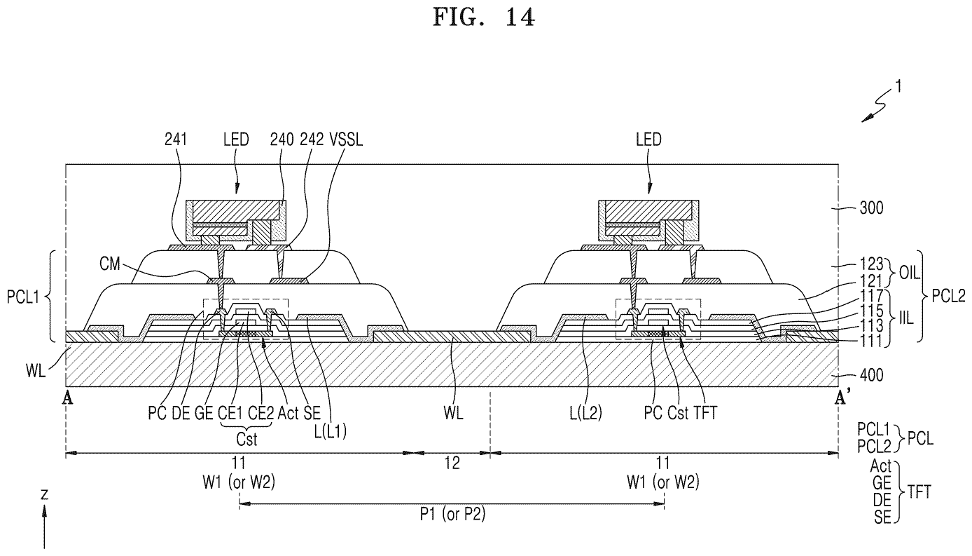

Referring to FIG. 14, the connecting line WL may be not embedded in the base layer 400 as in FIGS. 11 to 13, but may be located on the base layer 400. The first line L1 and the second line L2 may be to extend towards the connecting line WL arranged on the base layer 400 and may be in contact with a portion of the side surface of the connecting line WL.

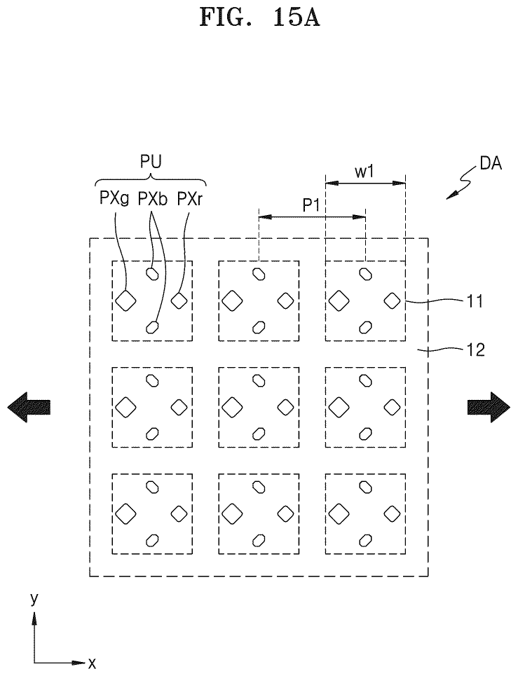

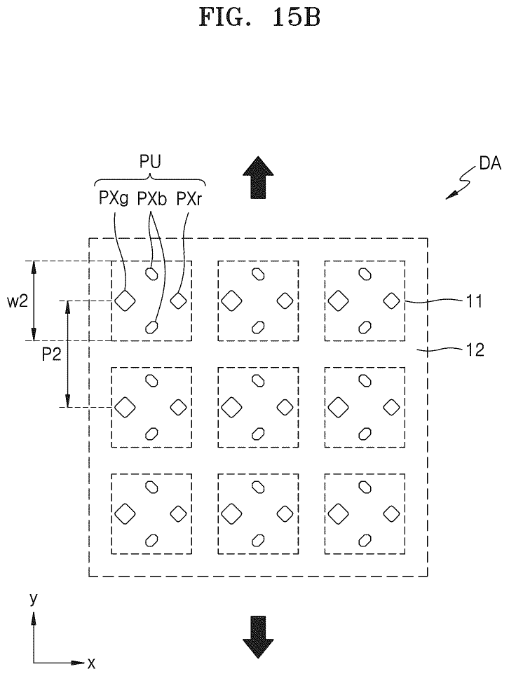

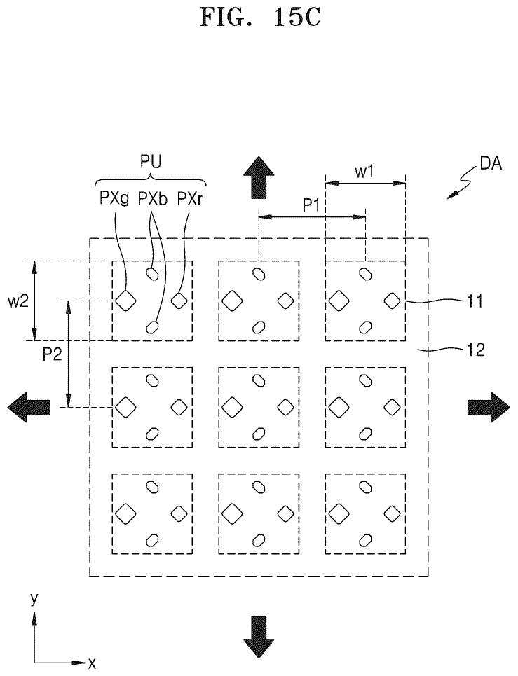

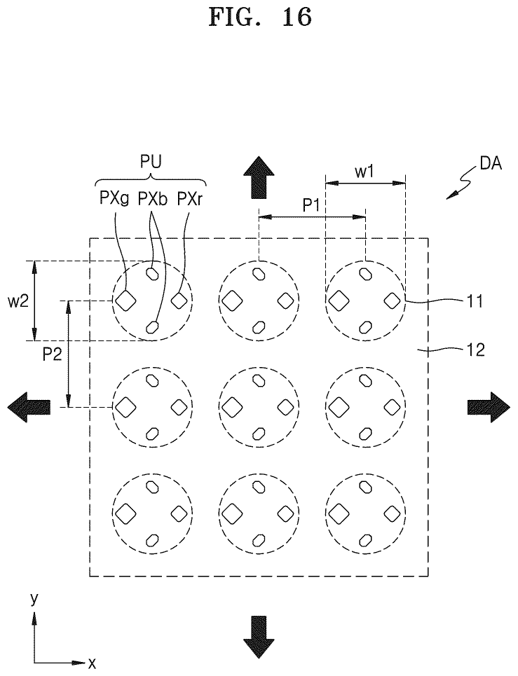

FIGS. 15A to 15C are plan views schematically showing a portion of the display area DA of the display device 1, according to one or more embodiments of the present disclosure. FIG. 16 is a plan view schematically showing a portion of the display area DA of the display device 1, according to one or more embodiments of the present disclosure.

Referring to FIGS. 15A to 15C, the display area DA may include the plurality of first areas 11 spaced and/or apart (e.g., spaced apart or separated) from each other at certain intervals, and the second area 12 around (e.g., surrounding) each of the first areas 11. The first areas 11 may be repeatedly arranged in (e.g., located at) the first direction (e.g., the x direction or the −x direction) and in the second direction (e.g., the y direction or the −y direction). The first areas 11 in FIGS. 15A to 15C may be arranged in a row-column configuration.

Each of the first areas 11 in FIGS. 15A to 15C may have an approximately quadrangular shape in plan view. In FIGS. 15A to 15C, the first areas 11 may be squares, but the first areas 11 may be rectangles and/or polygons. According to one or more other embodiments, as shown in FIG. 16, each of the first areas 11 may have an approximately rounded shape, e.g., a shape such as a circle or an oval, in plan view.

As described with reference to FIG. 4 and/or the like, the elongation of the first area 11 may be smaller than the elongation of the second area 12. Accordingly, the display area DA being stretched does not substantially indicate that the second area 12 may be stretched and deformed.

The display area DA of FIG. 15A may be stretched in the first direction (e.g., the x direction or the −x direction). Here, each first area 11 may have the first width w1 along the first direction (e.g., the x direction or the −x direction), and the plurality of first areas 11 may be spaced and/or apart (e.g., spaced apart or separated) from each other by the first pitch p1 along the first direction (e.g., the x direction or the −x direction). According to one or more embodiments, the distance ratio of the first width w1 of the first area 11 in the first direction (e.g., the x direction or the −x direction) to the first pitch p1 between the adjacent first areas 11 may be about 0.2 to about 0.65.

The display area DA of FIG. 15B may be stretched in the second direction (e.g., the y direction or the −y direction). Here, each first area 11 may have a second width w2 along the second direction (e.g., the y direction or the −y direction), and the plurality of first areas 11 may be spaced and/or apart (e.g., spaced apart or separated) from each other by a second pitch p2 along the second direction (e.g., the y direction or the −y direction). According to one or more embodiments, a distance ratio of the second width w2 of the first area 11 in the second direction (e.g., the y direction or the −y direction) to the second pitch p2 between the adjacent first areas 11 may be about 0.2 to about 0.65.

The display area DA of FIG. 15C may be stretched in the first direction (e.g., the x direction or the −x direction) and the second direction (e.g., the y direction or the −y direction). Here, each first area 11 may have the first width w1 along the first direction (e.g., the x direction or the −x direction), and the plurality of first areas 11 may be spaced and/or apart (e.g., spaced apart or separated) from each other by the first pitch p1 along the first direction (e.g., the x direction or the −x direction). Also, each first area 11 may have the second width w2 along the second direction (e.g., the y direction or the −y direction) and the plurality of first areas 11 may be spaced and/or apart (e.g., spaced apart or separated) from each other by the second pitch p2 along the second direction (e.g., the y direction or the −y direction). According to one or more embodiments, the distance ratio of the first width w1 of the first area 11 in the first direction (e.g., the x direction or the −x direction) to the first pitch p1 between the adjacent first areas 11 may be about 0.2 to about 0.65, and the distance ratio of the second width w2 of the first area 11 in the second direction (e.g., the y direction or the −y direction) to the second pitch p2 between the adjacent first areas 11 may be about 0.2 to about 0.65.

Referring to FIG. 16, the first areas 11 may have circular shapes in plan view. The display area DA of FIG. 16 may be stretched in the first direction (e.g., the x direction or the −x direction) and/or the second direction (e.g., the y direction or the −y direction). Here, each first area 11 may have the first width w1 along the first direction (e.g., the x direction or the −x direction), and the plurality of first areas 11 may be spaced and/or apart (e.g., spaced apart or separated) from each other by the first pitch p1 along the first direction (e.g., the x direction or the −x direction). Also, each first area 11 may have the second width w2 along the second direction (e.g., the y direction or the −y direction) and the plurality of first areas 11 may be spaced and/or apart (e.g., spaced apart or separated) from each other by the second pitch p2 along the second direction (e.g., the y direction or the −y direction). According to one or more embodiments, the distance ratio of the first width w1 of the first area 11 in the first direction (e.g., the x direction or the −x direction) to the first pitch p1 between the adjacent first areas 11 may be about 0.2 to about 0.65, and the distance ratio of the second width w2 of the first area 11 in the second direction (e.g., the y direction or the −y direction) to the second pitch p2 between the adjacent first areas 11 may be about 0.2 to about 0.65.

As described above, shapes of the first areas 11 may be suitably deformed. Here, a ‘pitch” of the first areas 11 may denote a distance connecting centers of the adjacent first areas 11 in a straight line, based on a virtual line along the elongation direction. Also, a “width” of each first area 11 may be defined to be the widest width based on the virtual line along the elongation direction. Because the first area 11 of FIG. 16 has a circular shape in plan view, the “width” of the first area 11 may be defined to be a diameter along the elongation direction.

As described with reference to FIGS. 15A to 15C, the distance ratio of the “width” of the first area 11 to the “pitch” of the plurality of first areas 11 may satisfy about 0.2 to about 0.65 along a direction of elongation. As described above, the shapes of first areas 11 may be suitably deformed, and in this case as well, the distance ratio of the “width” of the first area 11 to the “pitch” of the plurality of first areas 11 may satisfy about 0.2 to about 0.65 along the direction of elongation.

In the stretchable display device 1 (FIGS. 2A to 2E), if (e.g., when) the area of the first area 11 arranged in (e.g., located at) the pixel unit PU increases (e.g., if (e.g., when) the resolution increases), the width (or the area) of the second area 12 directly contributing to elongation may be decreased. Accordingly, in the display device 1 (FIGS. 2A to 2E) according to one or more embodiments of the present disclosure, the distance ratio of the “width” of the first area 11 to the “pitch” of the plurality of first areas 11 may be controlled or selected to provide the display device 1 (FIGS. 2A to 2E) in which the resolution may be increased and the elongation may be secured.

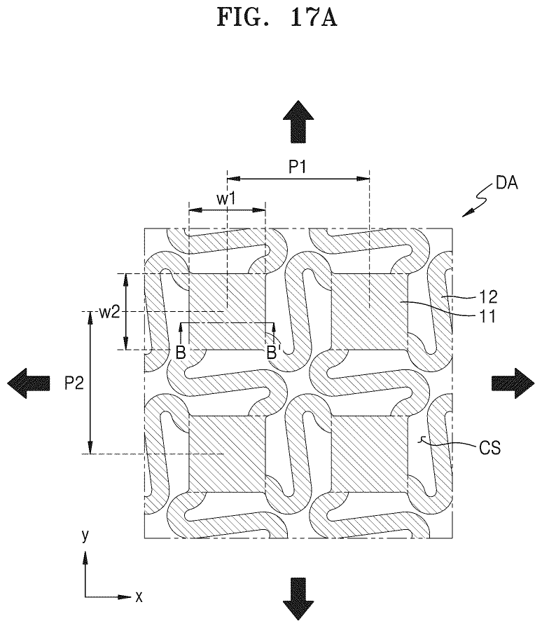

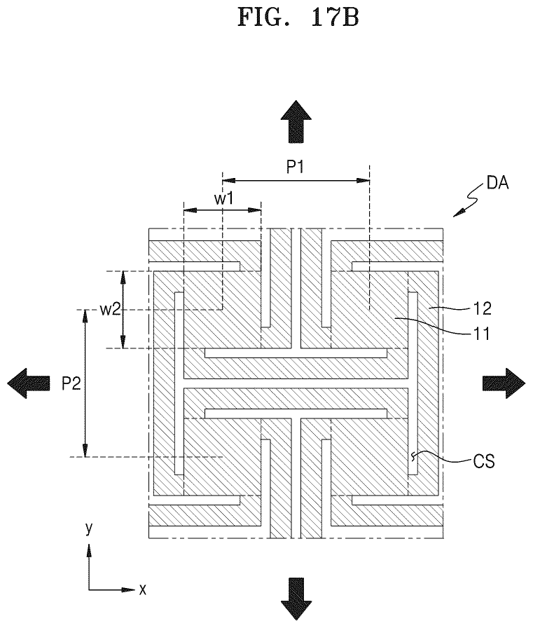

FIGS. 17A and 17B are plan views schematically showing excerpts of the display area DA of the display device 1, according to one or more embodiments of the present disclosure.

Unlike FIGS. 4 and 5 described above, the display device 1 shown in FIGS. 17A and 17B may include a substrate 100 corresponding to a base layer, and the substrate 100 may include an opening portion CS corresponding to an area excluding a plurality of first areas 11 (hereinafter, a plurality of first island portions 11) and a plurality of second areas 12 (hereinafter, a plurality of first bridge portions 12) connecting the plurality of first areas 11. For example, in the display device illustrated in FIGS. 17A and 17B, the structure includes the substrate 100 that serves as a base layer. This substrate 100 features the opening portion CS—a region that excludes both the plurality of first areas 11 (referred to as first island portions) and the plurality of second areas 12 (referred to as first bridge portions) that connect them. In the context of present disclosure and unless defined otherwise, “Island portions” are discrete, spaced-apart regions on the substrate that each include a light-emitting element. These portions are mechanically and electrically isolated from one another except through bridge portions, which provide flexible interconnections. The island portions are typically more rigid and may be structurally enhanced to house active display components, while the surrounding substrate and bridge portions allow for mechanical flexibility and stretchability.

Referring to FIG. 17A, the display device 1 may include, in the display area DA (see FIG. 1), the first areas 11 (hereinafter, first island portions 11) spaced and/or apart (e.g., spaced apart or separated) from each other in the first direction (e.g., the x direction or the −x direction) and the second direction (e.g., the y direction or the −y direction), and the second areas 12 (hereinafter, first bridge portions 12) connecting the adjacent first island portions 11.

Each first island portion 11 may be connected to the plurality of first bridge portions 12. For example, each first island portion 11 may be connected to four first bridge portions 12. Two first bridge portions 12 may be arranged on opposite sides of the first island portion 11 in the first direction (e.g., the x direction or the −x direction), and the remaining two first bridge portions 12 may be arranged on opposite sides of the first island portion 11 in the second direction (e.g., the y direction or the −y direction). According to one or more embodiments, the four first bridge portions 12 may be connected to four sides of the first island portion 11, respectively. The four first bridge portions 12 may be adjacent to corners of the first island portion 11, respectively.

The first bridge portions 12 may be spaced and/or apart (e.g., spaced apart or separated) from each other by the opening portion CS located between the first bridge portions 12. The first bridge portion 12 may have a serpentine shape. For example, as shown in FIG. 17A, the first bridge portion 12 may have a shape of approximately the letter “S”.

Referring to FIG. 17B, the display device 1 may include, in the display area DA (see FIG. 1), the plurality of first island portions 11 spaced and/or apart (e.g., spaced apart or separated) from each other in the first direction (e.g., the x direction or the −x direction) and the second direction (e.g., the y direction or the −y direction), and the plurality of first bridge portions 12 connecting the adjacent first island portions 11.

Each first island portion 11 may be connected to the plurality of first bridge portions 12. For example, each first island portion 11 may be connected to four first bridge portions 12. Two first bridge portions 12 may be arranged on opposite sides of the first island portion 11 in the first direction (e.g., the x direction or the −x direction), and the remaining two first bridge portions 12 may be arranged on opposite sides of the first island portion 11 in the second direction (e.g., the y direction or the −y direction). According to one or more embodiments, the four first bridge portions 12 may be connected to four sides of the first island portion 11, respectively. The four first bridge portions 12 may be adjacent to corners of the first island portion 11, respectively.

The first bridge portions 12 may be spaced and/or apart (e.g., spaced apart or separated) from each other by the opening portion CS located between the first bridge portions 12. According to one or more embodiments, the opening portion CS having an approximately (substantially) H-shape and the opening portion CS having an approximately (substantially) I-shape obtained by rotating the H-shape by 90 degrees may be alternately and repeatedly arranged along the first direction (e.g., the x direction or the −x direction) and the second direction (e.g., the y direction or the −y direction). Opposite end portions of each first bridge portion 12 may be respectively connected to the adjacent first island portions 11, and one side of each first bridge portion 12 may be spaced and/or apart (e.g., spaced apart or separated) from one side of the adjacent first island portion 11 and/or one side of another first bridge portion 12 by the opening portion CS.

According to one or more embodiments, the display device 1 may include, in the non-display area NDA (see FIG. 1), a plurality of second island portions spaced and/or apart (e.g., spaced apart or separated) from each other in the first direction (e.g., the x direction or the −x direction) and the second direction (e.g., the y direction or the −y direction), and a plurality of second bridge portions connecting the adjacent second island portions. Accordingly, the non-display area NDA of the display device 1 may also be stretched in one or more suitable directions. The second island portion and the second bridge portion may respectively have substantially the same shape or similar shapes as the first island portion 11 and the first bridge portion 12 of the display area DA described with reference to FIGS. 17A and 17B. According to one or more other embodiments of the present disclosure, the second island portion and the second bridge portion of the non-display area NDA may have different shapes from the first island portion 11 and the first bridge portion 12 of the display area DA, respectively.

In FIGS. 17A and 17B, the display area DA may be stretched in the first direction (e.g., the x direction or the −x direction) and the second direction (e.g., the y direction or the −y direction). Here, each first island portion 11 may have the first width w1 along the first direction (e.g., the x direction or the −x direction) and the plurality of first island portions 11 may be spaced and/or apart (e.g., spaced apart or separated) from each other by the first pitch p1 along the first direction (e.g., the x direction or the −x direction). Also, each first island portion 11 may have the second width w2 along the second direction (e.g., the y direction or the −y direction), and the plurality of first island portions 11 may be spaced and/or apart (e.g., spaced apart or separated) from each other by the second pitch p2 along the second direction (e.g., the y direction or the −y direction). According to one or more embodiments, the distance ratio of the first width w1 of the first island portion 11 in the first direction (e.g., the x direction or the −x direction) to the first pitch p1 between the adjacent first island portions 11 may be about 0.2 to about 0.65, and the distance ratio of the second width w2 of the first island portion 11 in the second direction (e.g., the y direction or the −y direction) to the second pitch p2 between the adjacent first island portions 11 may be about 0.2 to about 0.65.

In the stretchable display device 1 (FIGS. 2A to 2E), if (e.g., when) the area of the first area 11 arranged in (e.g., located at) the pixel unit PU increases (e.g., if (e.g., when) the resolution increases), the width (or the area) of the second area 12 directly contributing to elongation may be decreased. Accordingly, in the display device 1 (FIGS. 2A to 2E) according to one or more embodiments of the present disclosure, the distance ratio of the “width” of the first area 11 to the “pitch” of the plurality of first areas 11 may be controlled or selected to provide the display device 1 (FIGS. 2A to 2E) in which the resolution may be increased and the elongation may be secured.

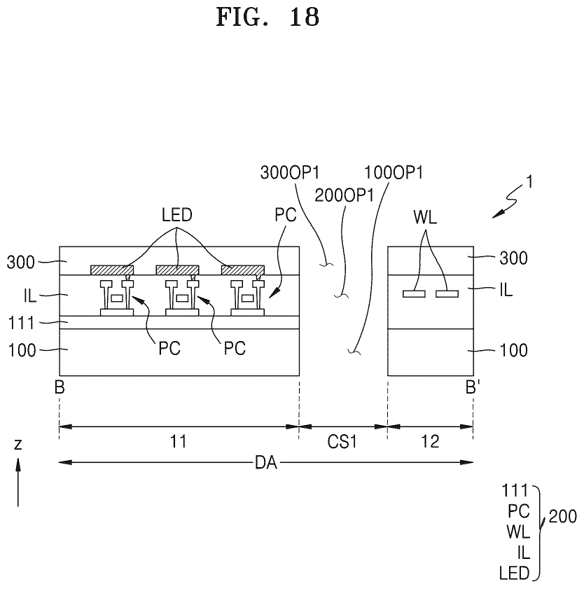

FIG. 18 is a cross-sectional view schematically showing the first island portion 11 and the first bridge portion 12, which may be arranged in (e.g., located at) the display area DA of the display device 1, according to one or more embodiments of the present disclosure. FIG. 18 may correspond to a cross-sectional view taken along a line B-B′ of FIG. 17A.

Referring to FIG. 18, the first island portion 11 and the first bridge portion 12, which may be arranged in (e.g., located at) the display area DA, may be spaced and/or apart (e.g., spaced apart or separated) from each other with a first opening portion CS1 therebetween. The first island portion 11 may include light-emitting elements LED and a circuit, for example, a pixel driving circuit portion PC, electrically connected thereto and driving the light-emitting elements LED, and the first bridge portion 12 may include a wire WL electrically connected to the pixel driving circuit portions PC arranged in (e.g., located at) the adjacent first island portions 11, respectively.

Referring to the first island portion 11, the buffer layer 111 including an inorganic insulating material may be arranged on the substrate 100, and the pixel driving circuit portion PC may be arranged on the buffer layer 111. An insulating layer IL including an inorganic insulating material and/or an organic insulating material may be arranged between the pixel driving circuit portion PC and the light-emitting element LED. The light-emitting element LED may be arranged on the insulating layer IL and electrically connected to the corresponding pixel driving circuit portion PC. The light-emitting elements LED may be to emit lights of different colors or lights of the same color. According to one or more embodiments, each of the light-emitting elements LED may be to emit red, green, and/or blue light. According to one or more embodiments, the light-emitting elements LED may be to emit white light. According to one or more other embodiments, each of the light-emitting elements LED may be to emit red, green, blue, and/or white light.

The substrate 100 may include a polymer resin such as polyether sulfone, polyacrylate, polyether imide, polyethylene naphthalate, polyethylene terephthalate, polyphenylene sulfide, polyimide, polycarbonate, cellulose triacetate, and/or cellulose acetate propionate. According to one or more embodiments, the substrate 100 may be a single layer including the polymer resin described above. According to one or more other embodiments, the substrate 100 may have a multi-layer structure including a base layer including the polymer resin described above, and/or a barrier layer including an inorganic insulating material. The substrate 100 including the polymer resin may be flexible, rollable, and/or bendable.

According to one or more embodiments, in FIG. 18, three pixel driving circuit portions PC may be arranged in (e.g., located at) each first island portion 11, and three light-emitting elements LED may be connected to each pixel driving circuit portion PC, but the present disclosure is not limited thereto. According to one or more other embodiments, the numbers of pixel driving circuit portions PC and light-emitting elements LED arranged in (e.g., located at) the first island portion 11 may be one, two, four or more.

The protecting layer 300 (or an encapsulation layer) may be arranged on the light-emitting element LED and may protect the light-emitting element LED from external force and/or moisture permeability. The protecting layer 300 may include an inorganic encapsulation layer and/or an organic encapsulation layer. According to one or more embodiments, the protecting layer 300 may have a structure in which an inorganic encapsulation layer including an inorganic insulating material, an organic encapsulation layer including an organic insulating material, and an inorganic encapsulation layer including an inorganic insulating material may be stacked on each other. According to one or more other embodiments, the protecting layer 300 may include an organic material such as resin. According to one or more embodiments, the protecting layer 300 may include urethane epoxy acrylate. The protecting layer 300 may include a photosensitive material, for example, a photoresist.

Referring to the first bridge portion 12, the insulating layer IL including an organic insulating material may be arranged on the substrate 100. The first bridge portion 12 that may be relatively deformed a lot if (e.g., when) the display device 1 may be stretched may not include (e.g., may exclude) a (e.g., any) layer including an inorganic insulating material, which may be easily cracked, unlike the first island portion 11. For example, the first bridge portion 12, which undergoes significant deformation when the display device is stretched, is formed on an insulating layer IL made of an organic insulating material. Unlike the first island portion 11, the bridge portion does not include any inorganic insulating layers, which are more prone to cracking under stress.

According to one or more embodiments, the substrate 100 corresponding to the first bridge portion 12 may have substantially the same stack structure as the substrate 100 corresponding to the first island portion 11. According to one or more embodiments, the substrate 100 corresponding to the first bridge portion 12 and the substrate 100 corresponding to the first island portion 11 may be polymer resin layers formed/provided together through substantially the same process. According to one or more other embodiments, the substrate 100 corresponding to the first bridge portion 12 may have a different stack structure from the substrate 100 corresponding to the first island portion 11. According to one or more embodiments, the substrate 100 corresponding to the first bridge portion 12 may have a multi-layer structure including a base layer including polymer resin and/or a barrier layer including an inorganic insulating material, and the substrate 100 corresponding to the first bridge portion 12 may have a structure of a polymer resin layer without a layer including an inorganic insulating material (e.g., a structure including a polymer resin layer and excluding a layer including an inorganic insulating material).

As described above, the wires WL of the first bridge portion 12 may be signal lines (e.g., a gate line, a data line, and/or the like) for providing an electrical signal to a transistor included in the pixel driving circuit portion PC of the first island portion 11, and/or voltage lines (e.g., a driving voltage line, an initialization voltage line, and/or the like) for providing a voltage. The protecting layer 300 may also be arranged on the first bridge portion 12. According to one or more other embodiments, the protecting layer 300 may not be present on the first bridge portion 12.

Referring to FIGS. 17A, 17B, and 18, the substrate 100 corresponding to the first island portion 11 and the substrate 100 corresponding to the first bridge portion 12 may be connected to each other, e.g., the substrate 100 corresponding to the first island portion 11 may connect to the substrate 100 corresponding to the first bridge portion 12. For example, the plan views of FIGS. 17A and 17B above may be substantially the same as the plan view of the substrate 100 of FIG. 18. For example, the substrate 100 may include an area corresponding to the first island portion 11, an area corresponding to the first bridge portion 12, and an opening 1000P1 having substantially the same shape as the first opening portion CS1.

Similarly, the protecting layer 300 corresponding to the first island portion 11 and the protecting layer 300 corresponding to the first bridge portion 12 may be connected to each other, e.g., the protecting layer 300 corresponding to the first island portion 11 may be connected to the protecting layer 300 corresponding to the first bridge portion 12. For example, the plan views of FIGS. 17A and 17B above may be substantially the same as the plan view of the protecting layer 300. For example, the protecting layer 300 may include an area corresponding to the first island portion 11, an area corresponding to the first bridge portion 12, and an opening 3000P1 having substantially the same shape as the first opening portion CS1.

A circuit-light-emitting element layer 200 between the substrate 100 and the protecting layer 300 may include the buffer layer 111, the pixel driving circuit portion PC, the wire WL, the insulating layer IL, and/or the light-emitting element LED. Similarly to the substrate 100, the plan views of FIGS. 17A and 17B above may be substantially the same as the plan view of the circuit-light-emitting element layer 200. For example, the circuit-light-emitting element layer 200 may include an opening 2000P1 having substantially the same shape as the first opening portion CS1.

In FIGS. 17A, 17B, and 18, a “width” of each first island portion 11 may be substantially the same as a width of the substrate 100. This may be because the circuit-light-emitting element layer 200 and the protecting layer 300 described with reference to FIG. 18 may be formed/provided on the substrate 100.

Hereinabove, a display device has been mainly described but the present disclosure is not limited thereto. For example, an electronic device including such a display device will also be within the scope of the present disclosure.

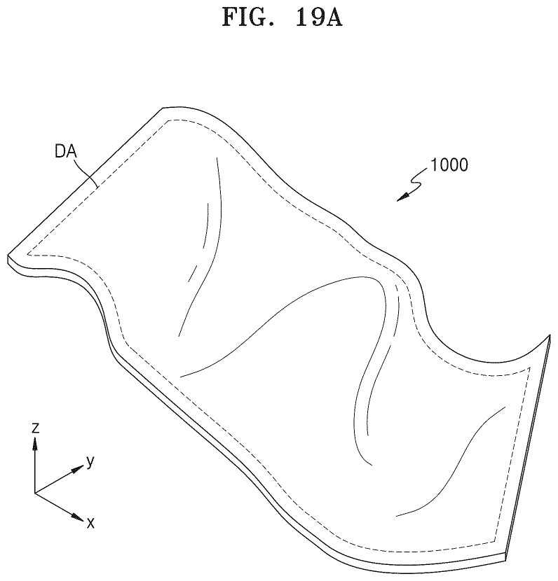

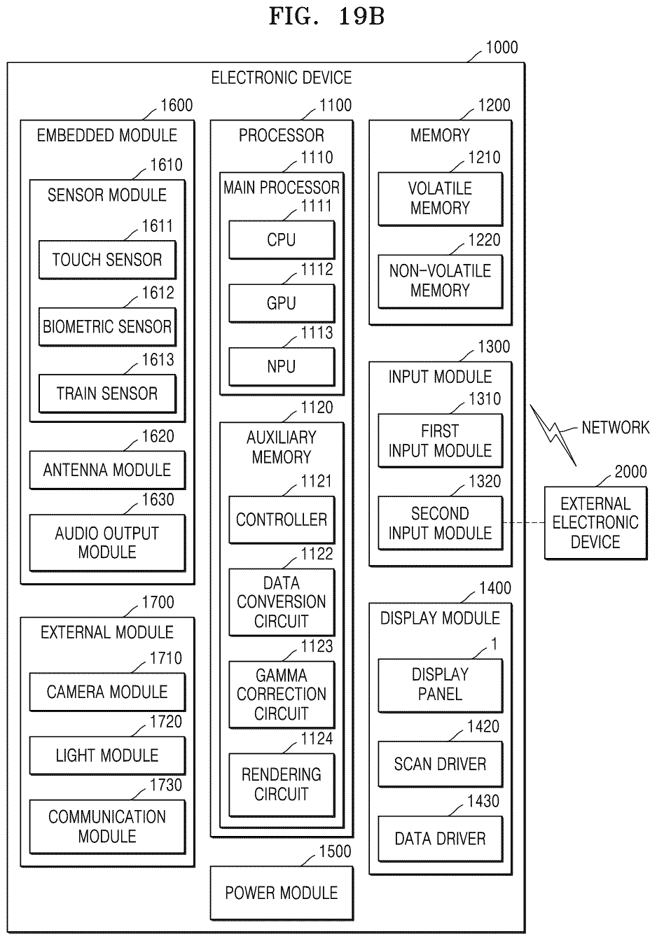

FIG. 19A is a perspective view schematically showing an electronic device 1000 including a display device, according to one or more embodiments of the present disclosure, and FIG. 19B is a block diagram schematically showing the electronic device 1000 including the display device 1, according to one or more embodiments of the present disclosure.

Referring to FIG. 19A, the electronic device 1000 may be freely deformed 3-dimensionally and provide a 3-dimensional image plane through the display area DA. The electronic device 1000 being freely deformed 3-dimensionally may be distinguished from an operation of an electronic device including a rollable display device, such as a case where a portion of a rolled-up display area may be visible to a user and another portion of the rolled-up display area may be unfolded to reveal the entire display area to the user (or a case where the entire unfolded display area may be visible to the user and the display area may be rolled up to reveal only a portion of the display area to the user). According to one or more embodiments of the present application, the electronic device 1000 may exhibit deformation, such as the area of the entire display area DA being increased and then decreased if (e.g., when) the electronic device 1000 may be deformed in the x direction, the y direction, and/or the z direction.

Referring to FIG. 19B, the electronic device 1000 may include a processor 1100, a memory 1200, an input module 1300 (e.g., an input device), a display module 1400 (e.g., a display), a power module 1500 (e.g., a power supply), an embedded module 1600 (e.g., an embedded device), and an external module 1700. According to one or more embodiments, in the electronic device 1000, at least one selected from among the above components may not be provided or one or more other components may be added. According to one or more embodiments, some components (e.g., the embedded module 1600) among the above components may be integrated with another component (e.g., the display module 1400).

The processor 1100 may execute software to control at least one other component (e.g., a hardware or software component) of the electronic device 1000 connected to the processor 1100 and perform one or more suitable data processes or operations. According to one or more embodiments, as at least a part of the data processes or operations, the processor 1100 may store, in a volatile memory 1210, a command or data received from another component (e.g., the input module 1300, a sensor module 1610 (e.g., a sensor), and/or a communication module 1730 (e.g., a communication device)), process the command or data stored in the volatile memory 1210, and store result data in a non-volatile memory 1220.

The processor 1100 may include a main processor 1110 and an auxiliary processor 1120. The main processor 1110 may include at least one selected from among a central processing unit (CPU) 1111 and an application processor (AP). The main processor 1110 may further include at least one selected from among a graphics processing unit (GPU) 1112, a communication processor (CP), and an image signal processor (ISP). The main processor 1110 may further include a neural processing unit (NPU) 1113. The NPU 1113 may be a processor specialized in processing an artificial intelligence model, and the artificial intelligence model may be generated through machine learning. The artificial intelligence model may include a plurality of artificial neural network layers. An artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and/or a combination thereof, but the present disclosure is not limited thereto. The artificial intelligence model may include, additionally or alternatively, a software structure, in addition to a hardware structure. The main processor 1110 may be implemented in a configuration (e.g., a single chip) in which at least two of the above-described processing units and processors may be integrated, or implemented in configurations (e.g., a plurality of chips) in which the above-described processing units and processors may be independent.

The auxiliary processor 1120 may include a controller 1121. The controller 1121 may include an interface conversion circuit and a timing control circuit. The controller 1121 may receive an image signal from the main processor 1110 and outputs image data by converting a data format of the image signal according to an interface specification of the display module 1400. The controller 1121 may output one or more suitable control signals desired or required to drive the display module 1400.

The auxiliary processor 1120 may further include data processing circuits such as a data conversion circuit 1122, a gamma correction circuit 1123, and/or a rendering circuit 1124. The data conversion circuit 1122 may receive image data from the controller 1121 and may compensate the image data so that an image may be displayed at desired or suitable luminance according to characteristics of the electronic device 1000 or user settings, or may convert the image data to reduce power consumption or compensate for afterimages. The gamma correction circuit 1123 may convert image data and/or a gamma reference voltage, so that an image displayed on the electronic device 1000 has desired or suitable gamma characteristics. The rendering circuit 1124 may receive image data from the controller 1121 and may render the image data in consideration of a pixel arrangement of the display device 1 applied to the electronic device 1000. At least one selected from among the data conversion circuit 1122, the gamma correction circuit 1123, and the rendering circuit 1124 may be integrated into another component (e.g., the main processor 1110 or the controller 1121). According to one or more embodiments, the auxiliary processor 1120 may be integrated into a data driver 1430.

The memory 1200 may store one or more suitable pieces of data utilized by at least one component (e.g., the processor 1100 or the sensor module 1610) of the electronic device 1000, and input data or output data for a command related to the one or more suitable pieces of data. The memory 1200 may include at least one selected from among the volatile memory 1210 and the non-volatile memory 1220.

The input module 1300 may receive a command or data to be utilized in a component (e.g., the processor 1100, the sensor module 1610, or an audio output module 1630 (e.g., an audio output device)) of the electronic device 1000 from an external source (e.g., the user or an external electronic device 2000) of the electronic device 1000.

The input module 1300 may include a first input module 1310 into which a command or data may be input from the user and a second input module 1320 into which a command or data may be input from the external electronic device 2000.

The first input module 1310 may include a microphone, a mouse, a keyboard, or a pen (e.g., a passive pen or an active pen). The first input module 1310 may include a touch input unit or a mechanical input unit, such as a button, a dome switch, a jog wheel, or a jog switch, located on a rear surface or a side surface of the electronic device 1000. The touch input unit may include a touchscreen layer of the display device 1.

The second input module 1320 may be connected, via wires or wirelessly, to any type (kind) of external electronic device 2000 connected to the electronic device 1000. According to one or more embodiments, the second input module 1320 may include a high-definition multimedia interface (HDMI), a universal serial bus (USB) interface, a secure digital (SD) card interface, or an audio interface. The second input module 1320 may include a connector for physically connecting the electronic device 1000 to the external electronic device 2000, for example, an HDMI connector, a USB connector, an SD card connector, or an audio connector (e.g., a headphones connector). The electronic device 1000 may perform an appropriate or suitable control related to the connected external electronic device 2000, based on the external electronic device 2000 being connected to the second input module 1320.

The display module 1400 provides visual information to the user. The display module 1400 may include the display device 1, a scan driver 1420, and the data driver 1430.

The display device 1 displays (outputs) information processed by the electronic device 1000. The display device 1 may display execution screen information of an application driven by the electronic device 1000 or user interface (UI) or graphical user interface (GUI) information according to the execution screen information.

The scan driver 1420 may be mounted on the display device 1, as a driving chip. In one or more embodiments, the scan driver 1420 may be directly formed/provided in the display device 1. For example, the scan driver 1420 may include an amorphous silicon thin-film transistor (TFT) gate (ASG) driver circuit, a low temperature polycrystalline silicon (LTPS) TFT gate driver circuit, or an oxide semiconductor TFT gate (OSG) driver circuit, which may be embedded in the display device 1. The scan driver 1420 receives a control signal from the controller 1121 and outputs scan signals to the display device 1 in response to the control signal.

The display device 1 may further include an emission control driver. The emission control driver outputs an emission control signal to the display device 1 in response to a control signal received from the controller 1121. The emission control driver may be provided separately from the scan driver 1420 or may be integrated into the scan driver 1420.

The data driver 1430 receives a control signal from the controller 1121, converts image data into a data voltage in the form of an analog voltage, in response to the control signal, and then outputs the data voltages to the display device 1.

The data driver 1430 may be integrated into some components of the auxiliary processor 1120. For example, the data driver 1430 may be provided as a timing controller embedded driver IC including the controller 1121.

The power module 1500 supplies power to components of the electronic device 1000. The power module 1500 may include a battery for charging a power voltage. Also, the power module 1500 may include a connecting port and the connecting port may be included in the second input module 1320 to which an external charger supplying power to charge the battery may be connected. In one or more embodiments, the power module 1500 may include a wireless power transmission/reception member to charge the battery in a wireless manner. The wireless power transmission/reception member may include a plurality of coil-shaped antenna radiators. The power module 1500 may include a power management integrated circuit (PMIC). The PMIC supplies improved or optimized power to each component of the electronic device 1000.

The electronic device 1000 may further include the embedded module 1600 and the external module 1700 (e.g., an external device). The embedded module 1600 may include the sensor module 1610, an antenna module 1620 (e.g., an antenna), and the audio output module 1630. The external module 1700 may include a camera module 1710, a light module 1720 (e.g., a light source), and the communication module 1730.

The sensor module 1610 may include touch electrodes and a touch sensor driver of the touchscreen layer of the display device 1. The sensor module 1610 may detect an input by the user's body or an input by a pen, and generate an electrical signal or data value corresponding to the input. The sensor module 1610 may include at least one selected from among a touch sensor 1611, a biometric sensor 1612, and a strain sensor 1613.

The touch sensor 1611 may generate a data value corresponding to coordinate information of the input by the user's body (e.g., a finger) or the input by the pen. The touch sensor 1611 may generate a data value based on a change in electrostatic capacity, a change in pressure, or a change in an electromagnetic field, caused by the input.

A biometric sensor 1512 may generate a data value for recognizing a part of the user's body (e.g., a fingerprint, an iris, or a face) or generate a data value corresponding to body information (e.g., blood pressure, moisture, a heart rate, or a body composition). The biometric sensor 1512 may utilize an optical method, an ultrasonic method, or a capacitive method.

The strain sensor 1613 may include layers, patterns, or wires, in which a measurable physical quantity changes according to stretching of the display device 1. For example, the strain sensor 1613 may include wires in which resistance and/or capacitance changes according to stretching of the display device 1. According to one or more other embodiments, the strain sensor 1613 may include an optical layer or optical pattern in which transmittance and/or reflectivity changes according to stretching of the display device 1.

The electronic device 1000 may improve quality of an image realized on the display device 1 or control the display device 1, based on the measured change in the physical quantity according to stretching of the display device 1. A control operation of the display device 1 may include, for example, an operation of displaying an operation image for protecting the display device 1, an operation of blocking a voltage for driving the display device 1, and an operation of stopping an stretching operation of the display device 1.

According to one or more embodiments, at least one selected from among the touch sensor 1611, the input sensor 1612, and the strain sensor 1613 may be embedded in the display device 1. For example, at least one selected from among the touch sensor 1611, the biometric sensor 1612, and the strain sensor 1613 may be formed/provided through a process consecutive to a process of forming/providing a pixel driving circuit portion and/or a light-emitting element of the display device 1. Accordingly, the display device 1 may operate as one selected from among input modules 1300 providing an input interface between the electronic device 1000 and the user while operating as the display module 1400 providing an output interface between the electronic device 1000 and the user.

At least two of the touch sensor 1611, the biometric sensor 1612, and the strain sensor 1613 may be formed/provided to be integrated into one sensing panel through substantially the same process. According to one or more embodiments, the sensing panel may be arranged between the display device 1 and a window cover arranged on a front surface of the display device 1, but the present disclosure is not disclosed thereto.

The antenna module 1620 may include one or more antennas for transmitting signals or power to the outside or receiving signals or power from the outside. According to one or more embodiments, the communication module 1730 may be to transmit a signal to the external electronic device or receive a signal from the external electronic device through an antenna suitable for a communication method. An antenna pattern of the antenna module 1620 may be integrated into one component (e.g., the display device 1) of the display module 1400 or into the input sensor 1612.

The audio output module 1630 may be a device for outputting an audio signal to the outside of the electronic device 1000, and may output audio data received from the communication module 1730 or stored in the memory 1200 in a call signal reception mode, a call mode or a recording mode, a voice recognition mode, or a broadcast reception mode. The audio output module 1630 may output an audio signal related to a function (for example, a call signal reception sound or a message reception sound) performed by the electronic device 1000. The audio output module 1630 may include a receiver and a speaker. At least one selected from among the receiver and the speaker may be an audio generating device attached to a rear surface of the display device 1 and outputting audio by vibrating the display device 1. The audio generating device may be a piezoelectric element or piezoelectric actuator that contracts and expands in response to an electrical signal, or an exciter that generates magnetic force by utilizing a voice coil to vibrate the display device 1.

The camera module 1710 may capture a still image and a moving image. According to one or more embodiments, the camera module 1710 may include one or more lenses, image sensors, or image signal processors. The camera module 1710 may further include an infrared camera capable of measuring presence of the user, a location of the user, and a line of sight of the user.

The light module 1720 may output a signal for notifying occurrence of an event by utilizing light of a light source or may provide light for obtaining an image.

Here, examples of occurrence of an event may include message reception, call signal reception, a missed call, an alarm, a schedule remainder, email reception, and battery charging capacity information. The light module 1720 may include a light-emitting diode or a xenon lamp. The light module 1720 may be to emit light of a single color or a plurality of colors to a front surface or a rear surface of the electronic device 1000. The light module 1720 may operate independently or in association with the camera module 1710.

The communication module 1730 may establish a wired or wireless communication channel between the electronic device 1000 and the external electronic device 2000, and support communication through an established communication channel. The communication module 1730 may include any one or both (e.g., simultaneously) of a wireless communication module, such as a cellular communication module, a short-range wireless communication module, or a global navigation satellite system (GNSS) communication module, and a wired communication module, such as a local area network (LAN) communication module or a power line communication module. The communication module 1730 may be to transmit and receive a wireless signal on the Internet by utilizing one selected from among wireless LAN (WLAN), wireless-fidelity (Wi-Fi), Wi-Fi direct, and digital living network alliance (DLNA) technologies. Also, the communication module 1730 may support short-range communication by utilizing at least one selected from among Bluetooth™, radio frequency identification (RFID), infrared data association (IrDA), ultra wideband (UWB), ZigBee, near field communication (NFC), Wi-Fi, Wi-Fi direct, and wireless universal serial bus (USB) technologies. One or more suitable types (kinds) of the communication module 1730 described above may be implemented as one chip or as separate chips.

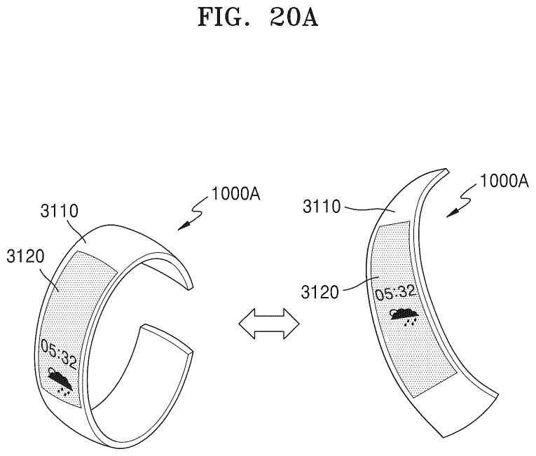

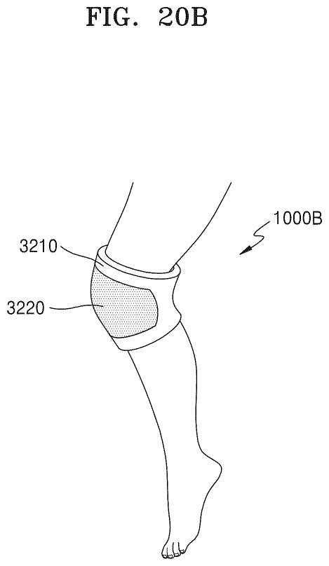

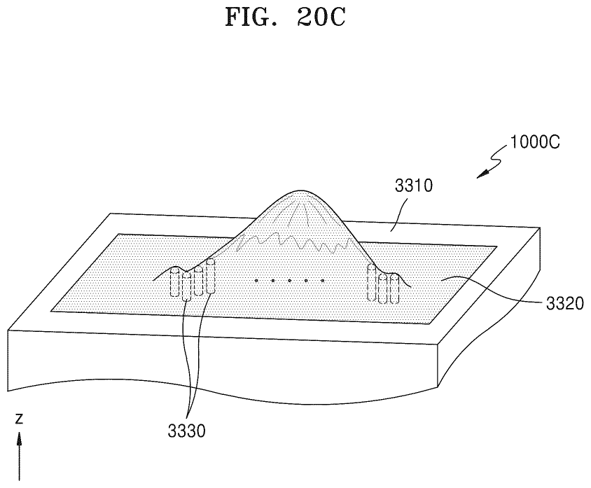

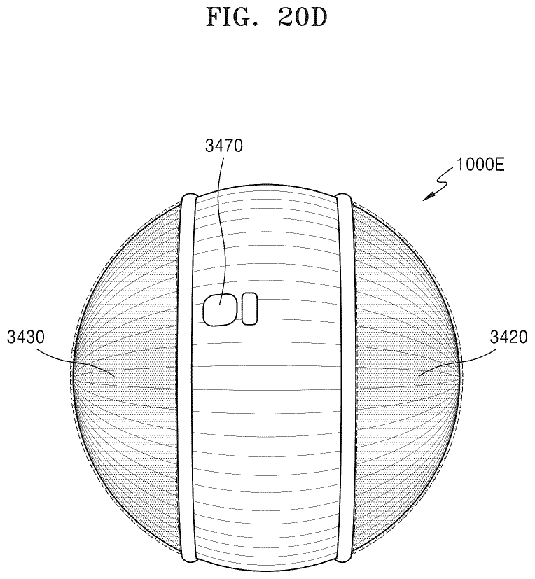

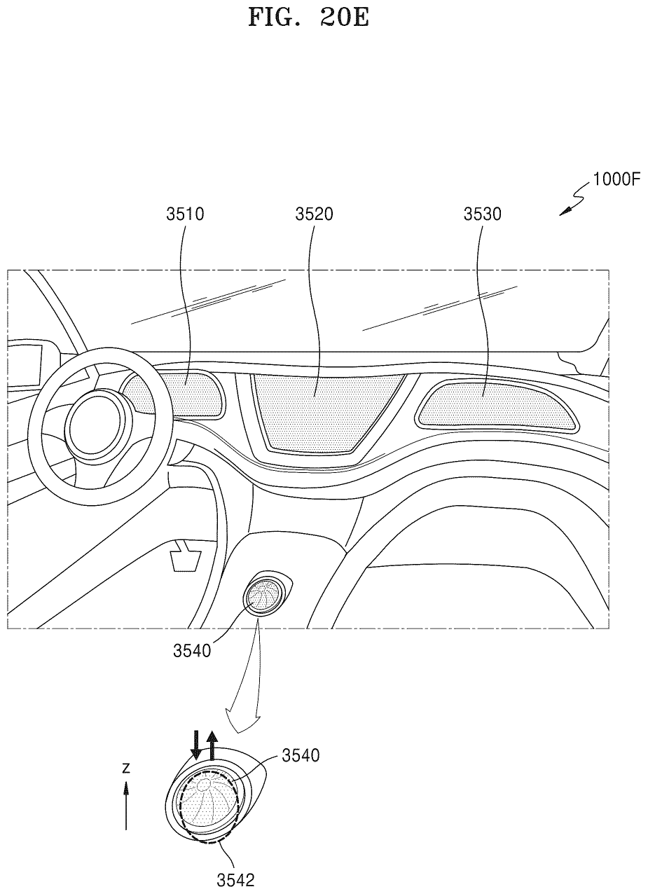

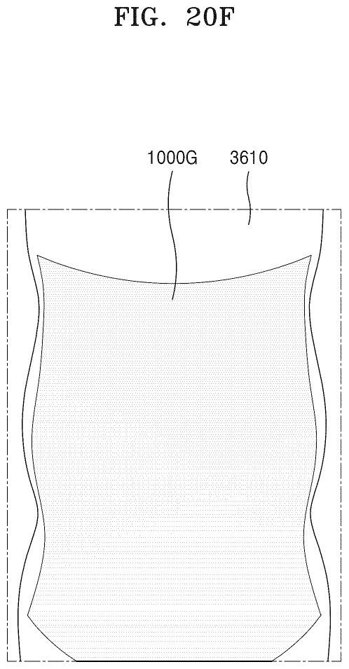

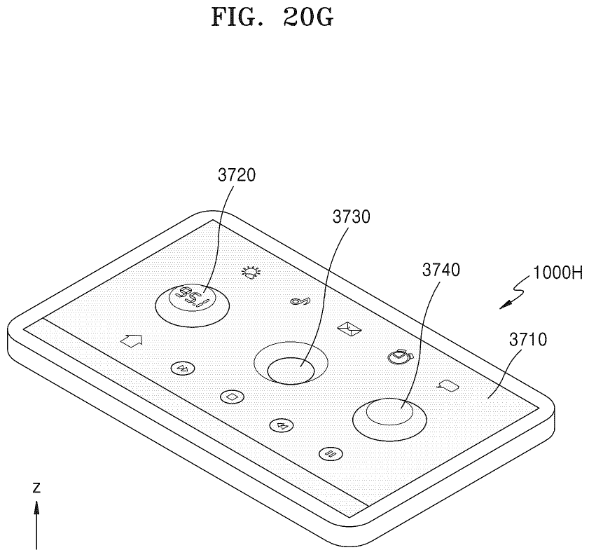

FIGS. 20A to 20G are each a perspective view schematically showing an example of an electronic device including a display device, according to one or more embodiments of the present disclosure.

Referring to FIG. 20A, a display device according to one or more embodiments of the present disclosure may be utilized for a wearable electronic device 1000A that may be worn on a part of a body of a user. The wearable electronic device 1000A may include a body portion 3110 and a display portion 3120 provided in the body portion 3110. The display device according to one or more embodiments of the present disclosure may be utilized as the display portion 3120 of the wearable electronic device 1000A. The wearable electronic device 1000A may be deformed as shown in FIG. 20A. According to one or more embodiments, the wearable electronic device 1000A may be utilized as a smart watch or a smart phone according to the user's choice.

FIG. 20B illustrates a medical electronic device 1000B. According to one or more embodiments, the medical electronic device 1000B may include a body portion 3210 and a light-emitting portion 3220. The display device according to one or more embodiments of the present disclosure may be utilized as the light-emitting portion 3220 of the medical electronic device 1000B. The light-emitting portion 3220 may be to emit, to a body of a patient, light of a substantially uniform wavelength band (e.g., infrared light, visible light, and/or the like). According to one or more embodiments, the body portion 3210 may include a stretchable and recoverable fiber material and have a structure capable of being worn on a body of a user.

FIG. 20C illustrates an educational electronic device 1000C. According to one or more embodiments, the educational electronic device 1000C may include a display portion 3320 provided in a housing 3310. The display portion 3320 may utilize a display device according to one or more embodiments of the present disclosure. An image of the sea with waves, a mountain covered with snow, a volcano with lava, and/or the like may be provided through the display portion 3320, and at this time, the display portion 3320 may be stretched in a height direction (e.g., a z direction) by reflecting the height of waves, mountain, or volcano. According to one or more embodiments, a portion of the display portion 3320 may be to 3-dimensionally display movement of the lava as a height thereof sequentially changes in a direction the lava flows. The educational electronic device 1000C may include a plurality of pins 3330 (or stroke portions) arranged on a rear surface of the display portion 3320 such that the display portion 3320 may be stretched in the height direction. An image displayed on the display portion 3320 may be 3-dimensionally realized to have heights as the pins 3330 move in the third direction (e.g., the z direction or the −z direction). FIG. 20C shows the educational electronic device 1000C, but the purpose thereof is not limited as long as information about an example image is provided.

FIG. 20D illustrates an electronic device 1000E according to one or more embodiments of the present disclosure including a robot. The robot may recognize movement or an object by utilizing a camera module 3470 (e.g., a camera) and display an example image to a user through display portions 3420 and 3430.

According to one or more embodiments, display devices according to one or more embodiments of the present disclosure may be stretched in one or more suitable directions as described above, and thus may be assembled to a body frame having a hemispherical shape, and accordingly, the robot may include hemispherical display portions 3420 and 3430.

FIG. 20E illustrates a vehicle display device 1000F as an electronic device according to one or more embodiments of the present disclosure. The vehicle display device 1000F may include a cluster 3510, a center information display (CID) 3520, and/or a co-driver display 3530. A display device according to one or more embodiments of the present disclosure may be stretchable in one or more suitable directions, and thus may be utilized for the cluster 3510, the CID 3520, and/or the co-driver display 3530 without being restricted by a shape of an internal frame of a vehicle.

FIG. 20E illustrates that the cluster 3510, the CID 3520, and/or the co-driver display 3530 may be separated from each other, but the present disclosure is not limited thereto. According to one or more other embodiments, two or more of the cluster 3510, the CID 3520, and the co-driver display 3530 may be integrated with each other.

According to one or more embodiments, the vehicle display device 1000F may include a button 3540 for representing an example image. Referring to an enlarged view of FIG. 20E, the hemispherical button 3540 may include an object 3542 providing a feeling of utilizing a button while moving in the z direction or the −z direction, and a display device arranged on the object 3542. According to one or more embodiments, if (e.g., when) the object 3542 has a 3-dimensionally rounded surface, the display device may also have the 3-dimensionally rounded surface.

FIG. 20F illustrates an electronic device according to one or more embodiments of the present disclosure being an advertising or exhibitory electronic device 1000G. According to one or more embodiments, the advertising or exhibitory electronic device 1000G may be installed at a fixed structure 3610, such as a wall or a pillar. If (e.g., when) the structure 3610 includes an uneven surface as shown in FIG. 20F, the advertising or exhibitory electronic device 1000G may also be arranged along the uneven surface of the structure 3610. According to one or more embodiments, the advertising or exhibitory electronic device 1000G may be installed at the structure 3610 by utilizing a thermal contraction film and/or the like.

FIG. 20G illustrates a controller as an electronic device 1000H according to one or more embodiments of the present disclosure. The controller may include an image type (kind) button. For example, the controller may include first to third button areas 3720 to 3740 provided as a partial area of a display portion 3710 protrudes in a z direction or protrudes in a −z direction (or sunken in the z direction). According to one or more embodiments, the first and third button areas 3720 and 3740 may protrude in the z direction, and the second button 3730 may protrude in the −z direction (or sunken in the z direction).

Overall, the configuration of the first area (e.g., the island portion) and the second area (e.g., the bridge portion connecting each island portion) of the display device improves the stretchability of the display device, which allows the display device to be folded, rolled, or bent and provides one or more shapes to display an image in response to the user's need and preference. Furthermore, a protecting layer of the display device may protect the protect the light-emitting element from external force and/or moisture permeability, and a data conversion circuit of the display device may be to display an image at suitable luminance or convert the image data to reduce power consumption or compensate for afterimages.

In the context of the present disclosure and unless otherwise defined, the terms “use/utilize,” “using/utilizing,” and “used/utilized” may be considered synonymous with the terms “utilize,” “utilizing,” and “utilized,” respectively.

A person of ordinary skill in the art would appreciate, in view of the present disclosure in its entirety, that each suitable feature of the one or more suitable embodiments of the present disclosure may be combined or combined with each other (or one another), partially or entirely, and may be technically interlocked and operated in one or more suitable ways, and each embodiment may be implemented independently of each other (or one another) or in conjunction with each other (or one another) in any suitable manner unless otherwise stated or implied.

The display device, the electronic device, the manufacturing device thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In concluding the detailed description, those skilled in the art will appreciate that many variations and modifications may be made to one or more embodiments of the present application without substantially departing from the principles of disclosure. Therefore, the disclosed embodiments of present disclosure are utilized in a generic and descriptive sense only and not for purposes of limitation.

The present disclosure has been described with reference to the embodiments shown in the drawings, but the embodiments are only examples and it would be understood by one of ordinary skill in the art that one or more suitable modifications and equivalent embodiments are possible. Accordingly, the true technical protection scope of the present disclosure will be defined by the technical ideas of the appended claims and equivalents thereof.

### REFERENCE NUMERALS

400: Base Layer
11: First Area (or Island Portion)
12: Second Area (or Bridge Portion)
WL: Connecting Line

What is claimed is:

1. A display device comprising:
a plurality of first areas separated from each other and comprising a light-emitting element; and
a second area arranged between adjacent first areas selected from among the plurality of first areas,
wherein a distance ratio of a first width of each of the plurality of first areas in a first direction to a first pitch by which the plurality of first areas are separated from each other is about 0.2 to about 0.65.

2. The display device of claim 1, wherein the display device is stretchable in the first direction.

3. The display device of claim 1, wherein, in a second direction crossing the first direction, a ratio of a second width of each of the plurality of first areas to a second pitch by which the plurality of first areas in the second direction are separated from each other is about 0.2 to about 0.65.

4. The display device of claim 3, wherein the display device is stretchable in the second direction.

5. The display device of claim 1, wherein the plurality of first areas comprise two adjacent first areas and the second area connects the two adjacent first areas, and
the first pitch denotes a shortest distance connecting center portions of the two adjacent first areas in a straight line along the first direction with the second area between the two adjacent first areas.

6. The display device of claim 1, further comprising a connecting line arranged in the second area and connecting the plurality of first areas.

7. The display device of claim 6, wherein the connecting line has a serpentine shape.

8. The display device of claim 6, wherein the connecting line comprises a stretchable and recoverable conductive material.

9. The display device of claim 8, wherein an elongation of the stretchable and recoverable conductive material is about 200% or less.

10. The display device of claim 1, further comprising a base layer comprising a stretchable and recoverable material,
wherein the plurality of first areas are arranged on the base layer.

11. The display device of claim 1, wherein the plurality of first areas have a first modulus and the second area has a second modulus, and
the first modulus is greater than the second modulus.

12. The display device of claim 11, wherein the plurality of first areas have a multi-layer structure comprising a first layer, a second layer on the first layer, and a third layer on the second layer, and
the first modulus is a maximum modulus value among the first layer to the third layer.

13. The display device of claim 1, wherein the plurality of first areas have a multi-layer structure comprising a first layer, a second layer on the first layer, and a third layer on the second layer, and
the first width is based on a greatest width among widths of the first layer to the third layer, based on the first direction.

14. The display device of claim 1, wherein a shape of each of the plurality of first areas comprises a polygonal shape and/or a shape in which at least a portion is rounded.

15. A display device comprising:
a plurality of island portions separated from each other and comprising a light-emitting element; and
a plurality of bridge portions connecting adjacent island portions among the plurality of island portions,
wherein a distance ratio of a first width of each of the plurality of island portions in a stretchable first direction to a first pitch by which the plurality of island portions are separated from each other is about 0.2 to about 0.65.

16. The display device of claim 15, wherein, in a stretchable second direction crossing the first direction, a ratio of a second width of each of the plurality of island portions to a second pitch by which the plurality of island portions in the second direction are separated from each other is about 0.2 to about 0.65.

17. The display device of claim 15, wherein each of the plurality of bridge portions has a serpentine shape.

18. The display device of claim 15, wherein the plurality of island portions comprise a first island portion and a second island portion, the first island portion being adjacent to the second island portion, and the plurality of island portions comprise a first bridge portion connecting the first island portion to the second island portion, and
the first pitch denotes a width connecting a center portion of the first island portion and a center portion of the second island portion in a straight distance along the first direction with the first bridge portion between the first island portion and the second island portion.

19. An electronic device comprising a display device,
wherein the display device comprises:
a plurality of first areas separated from each other and comprising a light-emitting element; and
a second area arranged between adjacent first areas selected from among the plurality of first areas,
wherein a distance ratio of a first width of each of the plurality of first areas in a first direction to a first pitch by which the plurality of first areas are separated from each other is about 0.2 to about 0.65.

20. The electronic device of claim 19, further comprising a frame fixing the display device.
